(19) United States
(12) Patent Application Publication
(10) Pub. No.: US 2023/0332048 A1
(43) Pub. Date: Oct. 19, 2023

(54) LIGHT ABSORPTION ANISOTROPIC FILM, OPTICAL FILM, AND LIQUID CRYSTAL DISPLAY DEVICE

(71) Applicant: FUJIFILM Corporation, Tokyo (JP)

(72) Inventors: Wataru HOSHINO, Kanagawa (JP); Naoya NISHIMURA, Kanagawa (JP); Shinya WATANABE, Kanagawa (JP)

(73) Assignee: FUJIFILM Corporation, Tokyo (JP)

(21) Appl. No.: 18/339,728

(22) Filed: Jun. 22, 2023

Related U.S. Application Data
(63) Continuation of application No. PCT/JP2021/046623, filed on Dec. 16, 2021.

(30) Foreign Application Priority Data
Dec. 25, 2020 (JP) 2020-217773

(51) Int. Cl. C09K 19/60; C09K 19/38; G02B 5/00

(52) U.S. Cl. CPC C09K 19/601; C09K 19/3852; G02B 5/003; G02F 1/133633

(57) ABSTRACT

A light absorption anisotropic film, an optical film, and a liquid crystal display device, with less defects and a high alignment degree even when the concentration of a dichroic substance is increased. The light absorption anisotropic film is formed of a liquid crystal composition containing a liquid crystal compound, a dichroic substance represented by Formula (C-1), a dichroic substance represented by Formula (C-2), in which a total content of the dichroic substances represented by Formula (C-1) and Formula (C-2) is 4.5% by mass or greater with respect to a total mass of a solid content of the liquid crystal composition, and the liquid crystal compound is vertically aligned. When R^{a1} and R^{a2} represent the same group, —N(R^{b11})(R^{b12}) and —N(R^{b21})(R^{b22}) are groups different from each other. When R^{a1} and R^{a2} represent different groups, —N(R^{b11})(R^{b12}) and —N(R^{b21})(R^{b22}) may be groups that are the same as or different from each other.

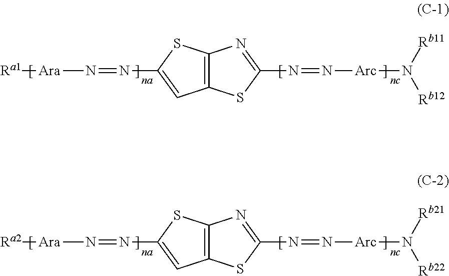

### CROSS-REFERENCE TO RELATED APPLICATIONS

This application is a Continuation of PCT International Application No. PCT/JP2021/046623 filed on Dec. 16, 2021, which claims priority under 35 U.S.C. § 119(a) to Japanese Patent Application No. 2020-217773 filed on Dec. 25, 2020. The above applications are hereby expressly incorporated by reference, in its entirety, into the present application.

### BACKGROUND OF THE INVENTION

### 1. Field of the Invention

The present invention relates to a light absorption anisotropic film, an optical film, and a liquid crystal display device.

### 2. Description of the Related Art

In order to prevent peeping into an image display device and control the viewing angle, a technique of using a light absorption anisotropic film having an absorption axis in the thickness direction is known. For example, JP2009-145776A discloses a viewing angle control system including a polarizer (light absorption anisotropic film) which contains a dichroic substance and in which the angle between an absorption axis and a normal line of a film surface is in a range of 0° to 45°.

### SUMMARY OF THE INVENTION

In order to prevent peeping into an image display device and control the viewing angle, it is important to ensure high light shielding properties. Therefore, it is important to increase the concentration of a dichroic substance in a light absorption anisotropic film and to align the dichroic substance in a photo-alignment film with a high alignment degree.

However, in a case where the concentration of the dichroic substance is increased, defects derived from the dichroic substance may occur in the light absorption anisotropic film.

Therefore, an object of the present invention is to provide a light absorption anisotropic film, an optical film, and a liquid crystal display device, with less defects and a high alignment degree even in a case where the concentration of a dichroic substance is increased.

As a result of intensive examination conducted by the present inventors in order to achieve the above-described object, it was found that a light absorption anisotropic film with less defects and a high alignment degree can be obtained by using two or more kinds of dichroic substances having different structures even in a case where the concentration of the dichroic substance is 4.5% by mass or greater, which is high, with respect to the total mass of the solid content of the liquid crystal composition.

That is, the present inventors found that the above-described problems can be solved by employing the following configurations.
[1] Alight absorption anisotropic film formed of a liquid crystal composition containing a liquid crystal compound, a dichroic substance represented by Formula (C-1), a dichroic substance represented by Formula (C-2), in which a total content of the dichroic substance represented by Formula (C-1) and the dichroic substance represented by Formula (C-2) is 4.5% by mass or greater with respect to a total mass of a solid content of the liquid crystal composition, and the liquid crystal compound is vertically aligned,
in Formula (C-1) and Formula (C-2), R^{a1} and R^{a2} each independently represent a hydrogen atom, a monovalent aliphatic hydrocarbon group having 1 to 20 carbon atoms which may have a monovalent substituent, or a monovalent group in which —CH₂— constituting a monovalent aliphatic hydrocarbon group having 1 to 20 carbon atoms which may have a monovalent substituent is substituted with a divalent substituent, Ara and Arc each independently represent a divalent aromatic group which may have a monovalent substituent, R^{b11}, R^{b21}, and R^{b22} each independently represent a hydrogen atom, a monovalent aliphatic hydrocarbon group having 1 to 20 carbon atoms which may have a monovalent substituent, or a monovalent group in which —CH₂— constituting a monovalent aliphatic hydrocarbon group having 1 to 20 carbon atoms which may have a monovalent substituent is substituted with a divalent substituent, R^{b12} represents a monovalent aliphatic hydrocarbon group having 1 to 20 carbon atoms which may have a monovalent substituent or a monovalent group in which —CH₂— constituting a monovalent aliphatic hydrocarbon group having 1 to 20 carbon atoms which may have a monovalent substituent is substituted with a divalent substituent, na and nc each independently represent an integer of 0 to 3, where na+nc is 2 or greater, where in a case where R^{a1} and R^{a2} represent the same group, —N(R^{b11})(R^{b12}) and —N(R^{b21})(R^{b22}) are groups different from each other, and in a case where R^{a1} and R^{a2} represent different groups, —N(R^{b11})(R^{b12}) and —N(R^{b21})(R^{b22}) may be groups that are the same as or different from each other.
[2] The light absorption anisotropic film according to [1], in which the total content of the dichroic substance represented by Formula (C-1) and the dichroic substance represented by Formula (C-2) is 6.5% by mass or greater with respect to the total mass of the solid content of the liquid crystal composition.
[3] The light absorption anisotropic film according to [1] or [2], in which a mass ratio of a content of the dichroic substance represented by Formula (C-1) to a content of the dichroic substance represented by Formula (C-2) in the liquid crystal composition is in a range of 0.100 to 10.0.
[4] The light absorption anisotropic film according to any one of [1] to [3],
in which in Formula (C-1), a value of a Hansen solubility parameter of R¹² is greater than or equal to a value of a Hansen solubility parameter of R^{b11},
in Formula (C-2), a value of a Hansen solubility parameter of R^{b22} is greater than or equal to a value of a Hansen solubility parameter of R^{b21},
an absolute value of a difference in the Hansen solubility parameter between R^{b12} in Formula (C-1) and R^{b22} in Formula (C-2) is 3.0 or less.
[5] The light absorption anisotropic film according to [4], in which the absolute value of the difference in the Hansen solubility parameter between R^{b12} in Formula (C-1) and R^{b22} in Formula (C-2) is 1.0 or less.
[6] The light absorption anisotropic film according to any one of [1] to [5], in which R^{b22} in Formula (C-2) represents a monovalent aliphatic hydrocarbon group having 1 to 20 carbon atoms which has a monovalent substituent or a monovalent group in which —CH₂— constituting a monovalent aliphatic hydrocarbon group having 1 to 20 carbon atoms which may have a monovalent substituent is substituted with a divalent substituent.
[7] The light absorption anisotropic film according to any one of [1] to [6], in which in R^{b12} in Formula (C-1), the monovalent substituent is a hydroxyl group, a halogen atom, a cyano group, or a sulfonic acid group, and the divalent substituent is —O—, —C(═O)—, —N(R^{c1})—, or a group obtained by combining two or more of these groups, where R^{c1} represents a hydrogen atom or an alkyl group.
[8] The light absorption anisotropic film according to any one of [1] to [7], in which the liquid crystal compound includes a polymer liquid crystal compound.
[9] An optical film comprising: a transparent film base material; and the light absorption anisotropic film according to any one of [1] to [8] which is disposed on the transparent film base material.
[10] The optical film according to [9], further comprising: an alignment film between the transparent film base material and the light absorption anisotropic film.
[11] The optical film according to [9] or [10], further comprising: a polarizer which has an absorption axis in a plane, in which the optical film is used to control a viewing angle.
[12] A display device comprising: the optical film according to [11]; and a display element.

According to the present invention, it is possible to provide a light absorption anisotropic film, an optical film, and a liquid crystal display device, with less defects and a high alignment degree even in a case where the concentration of a dichroic substance is increased.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Further, in the present specification, the numerical ranges shown using “to” indicate ranges including the numerical values described before and after “to” as the lower limits and the upper limits.

Further, in the present specification, materials corresponding to respective components may be used alone or in combination of two or more kinds thereof. Here, in a case where two or more kinds of materials corresponding to respective components are used in combination, the content of the components indicates the total content of the combined materials unless otherwise specified.

Further, in the present specification, “(meth)acrylate” denotes “acrylate” or “methacrylate”, “(meth)acryl” denotes “acryl” or “methacryl”, “(meth)acryloyl” denotes “acryloyl” or “methacryloyl”, and “(meth)acrylic acid” denotes “acrylic acid” or “methacrylic acid”.

In the present invention, the dichroic substance denotes a coloring agent having different absorbances depending on the direction.

Further, in the present specification, the term “transparent” denotes that the light transmittance in a visible light wavelength range of 380 to 780 nm is 60% or greater unless otherwise specified. The light transmittance is measured using JIS (Japanese Industrial Standards) K 7375: 2008 “Plastic-Determination of total luminous transmittance and reflectance”.

[Light Absorption Anisotropic Film]

A light absorption anisotropic film according to the embodiment of the present invention is a light absorption anisotropic film formed of a liquid crystal composition containing a liquid crystal compound, a dichroic substance represented by Formula (C-1) (hereinafter, also referred to as “dichroic substance C-1”), a dichroic substance represented by Formula (C-2) (hereinafter, also referred to as “dichroic substance C-2”), in which the total amount of the dichroic substance C-1 and the dichroic substance C-2 is 4.5% by mass or greater with respect to the total mass of the solid content of the liquid crystal composition, and the liquid crystal compound is vertically aligned.

The light absorption anisotropic film according to the embodiment of the present invention has less defects and a high alignment degree even though the content of the dichroic substance is high. The details of the reason for this are not clear, but it is assumed as follows.

In a case where a light absorption anisotropic film containing a high concentration of a dichroic substance, the dichroic substance is likely to be crystallized in the process of forming the light absorption anisotropic film, and the crystallized dichroic substance may cause defects in the light absorption anisotropic film.

Here, the dichroic substance C-1 and the dichroic substance C-2 contained in the light absorption anisotropic film according to the embodiment of the present invention have structures similar to each other, but the compounds are not completely the same as each other. Therefore, it is assumed that occurrence of defects caused in a case where the same compound is used in a large amount can be suppressed while the effect of improving the alignment degree obtained by using dichroic substances having structures similar to each other is ensured.

[Liquid Crystal Composition]

The liquid crystal composition used for forming the light absorption anisotropic film according to the embodiment of the present invention contains a liquid crystal compound, a dichroic substance C-1, and a dichroic substance C-2. The liquid crystal composition may contain, as necessary, a dichroic substance other than the dichroic substance C-1 and the dichroic substance C-2, a solvent, a polymerization initiator, an interface improver, a vertical alignment agent, and a component other than the components described above.

Hereinafter, each component will be described.

<Liquid Crystal Compound>

The liquid crystal composition contains a liquid crystal compound. In a case where the composition contains a liquid crystal compound, the dichroic substances can be aligned with a high alignment degree while the precipitation of the dichroic substances is suppressed.

The liquid crystal compound is a liquid crystal compound that does not exhibit dichroism.

As the liquid crystal compound, both a low-molecular-weight liquid crystal compound and a polymer liquid crystal compound can be used, but a polymer liquid crystal compound is more preferable from the viewpoint of obtaining a high alignment degree. Here, the “low-molecular-weight liquid crystal compound” indicates a liquid crystal compound having no repeating units in the chemical structure. Here, the “polymer liquid crystal compound” indicates a liquid crystal compound having a repeating unit in the chemical structure.

Examples of the low-molecular-weight liquid crystal compound include liquid crystal compounds described in JP2013-228706A.

Examples of the polymer liquid crystal compound include thermotropic liquid crystal polymers described in JP2011-237513A. Further, the polymer liquid crystal compound may contain a crosslinkable group (such as an acryloyl group or a methacryloyl group) at a terminal.

The liquid crystal compound may be used alone or in combination of two or more kinds thereof.

From the viewpoint that the alignment degree of the light absorption anisotropic film is more excellent, it is preferable that the liquid crystal compound contains a polymer liquid crystal compound.

From the viewpoint that the alignment degree of the dichroic substance is more excellent, it is preferable that the liquid crystal compound is a polymer liquid crystal compound having a repeating unit represented by Formula (3-1) (hereinafter, also referred to as “repeating unit (3-1)”).

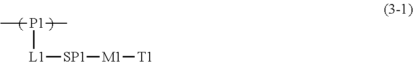

In Formula (3-1), P1 represents the main chain of the repeating unit, L1 represents a single bond or a divalent linking group, SP1 represents a spacer group, M1 represents a mesogen group, and T1 represents a terminal group.

Further, in the repeating unit (3-1), the difference between the log P value of P1, L1, and SP1 and the log P value of M1 is preferably 4 or greater. The difference is still more preferably 4.5 or greater. The repeating unit is in a state in which the compatibility between the mesogen group and the structure from the main chain to the spacer group is low because the log P value of the main chain, L1, and the spacer group and the log P value of the mesogen group are separated by a predetermined value or greater. In this manner, it is assumed that since the crystallinity of the polymer liquid crystal compound increases, the alignment degree of the polymer liquid crystal compound increases. As described above, it is assumed that in a case where the alignment degree of the polymer liquid crystal compound is high, the compatibility between the polymer liquid crystal compound and the dichroic substance is decreased (that is, the crystallinity of the dichroic substance is improved), and thus the alignment degree of the dichroic substance is improved. As a result, it is considered that the alignment degree of the light absorption anisotropic film to be obtained is increased.

Specific examples of the main chain of the repeating unit represented by P1 include groups represented by Formulae (P1-A) to (P1-D). Among these, from the viewpoints of diversity and handleability of a monomer serving as a raw material, a group represented by Formula (P1-A) is preferable.

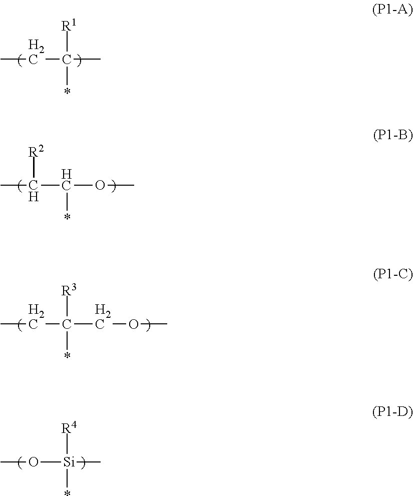

In Formulae (P1-A) to (P1-D), “*” represents a bonding position with respect to L1 in Formula (3-1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The alkyl group may be a linear or branched alkyl group or an alkyl group having a cyclic structure (cycloalkyl group). Further, the number of carbon atoms of the alkyl group is preferably in a range of 1 to 5.

It is preferable that the group represented by Formula (P1-A) is a unit of a partial structure of poly(meth)acrylic acid ester obtained by polymerization of (meth)acrylic acid ester.

It is preferable that the group represented by Formula (P1-B) is an ethylene glycol unit formed by ring-opening polymerization of an epoxy group of a compound containing the epoxy group.

It is preferable that the group represented by Formula (P1-C) is a propylene glycol unit formed by ring-opening polymerization of an oxetane group of a compound containing the oxetane group.

It is preferable that the group represented by Formula (P1-D) is a siloxane unit of a polysiloxane obtained by polycondensation of a compound containing at least one of an alkoxysilyl group or a silanol group. Here, examples of the compound containing at least one of an alkoxysilyl group or a silanol group include a compound containing a group represented by Formula SiR¹⁴(OR¹⁵)₂—. In the formula, R¹⁴ has the same definition as that for R¹⁴ in Formula (P1-D), and a plurality of R¹⁵'s each independently represent a hydrogen atom or an alkyl group having 1 to 10 carbon atoms.

L1 represents a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom or an alkyl group having 1 to 6 carbon atoms which may have a substituent (described below).

In a case where P1 represents a group represented by Formula (P1-A), from the viewpoint that the alignment degree of the light absorption anisotropic film is more excellent, it is preferable that L1 represents a group represented by —C(O)O—.

In a case where P1 represents a group represented by any of Formulae (P1-B) to (P1-D), from the viewpoint that the alignment degree of the light absorption anisotropic film is more excellent, it is preferable that L1 represents a single bond.

From the viewpoints of easily exhibiting liquid crystallinity and the availability of raw materials, it is preferable that the spacer group represented by SP1 has at least one structure selected from the group consisting of an oxyethylene structure, an oxypropylene structure, a polysiloxane structure, and an alkylene fluoride structure.

Here, as the oxyethylene structure represented by SP1, a group represented by *—(CH₂—CH₂O)ₙ₁—* is preferable. In the formula, n1 represents an integer of 1 to 20, and * represents a bonding position with respect to L1 or M1 in Formula (3-1). From the viewpoint that the alignment degree of the light absorption anisotropic film is more excellent, n1 represents preferably an integer of 2 to 10, more preferably an integer of 2 to 4, and most preferably 3.

Further, from the viewpoint that the alignment degree of the light absorption anisotropic film is more excellent, a group represented by *—(CH(CH₃)—CH₂O)ₙ₂—* is preferable as the oxypropylene structure represented by SP1. In the formula, n2 represents an integer of 1 to 3, and “*” represents a bonding position with respect to L1 or M1.

Further, from the viewpoint that the alignment degree of the light absorption anisotropic film is more excellent, a group represented by *—(Si(CH₃)₂—O)ₙ₃—* is preferable as the polysiloxane structure represented by SP1. In the formula, n3 represents an integer of 6 to 10, and “*” represents a bonding position with respect to L1 or M1.

Further, from the viewpoint that the alignment degree of the light absorption anisotropic film is more excellent, a group represented by *—(CF₂—CF₂)ₙ₄—* is preferable as the alkylene fluoride structure represented by SP1. In the formula, n4 represents an integer of 6 to 10, and “*”, represents a bonding position with respect to L1 or M1.

The mesogen group represented by M1 is a group showing a main skeleton of a liquid crystal molecule that contributes to liquid crystal formation. A liquid crystal molecule exhibits liquid crystallinity which is in an intermediate state (mesophase) between a crystal state and an isotropic liquid state. The mesogen group is not particularly limited, and for example, particularly description on pages 7 to 16 of “Flussige Kristalle in Tabellen II” (VEB Deutsche Verlag fur Grundstoff Industrie, Leipzig, 1984) and particularly the description in Chapter 3 of “Liquid Crystal Handbook” (Maruzen, 2000) edited by Liquid Crystal Handbook Editing Committee can be referred to.

As the mesogen group, for example, a group having at least one cyclic structure selected from the group consisting of an aromatic hydrocarbon group, a heterocyclic group, and an alicyclic group is preferable.

From the viewpoint that the alignment degree of the light absorption anisotropic film is more excellent, the mesogen group contains preferably an aromatic hydrocarbon group, more preferably two to four aromatic hydrocarbon groups, and still more preferably three aromatic hydrocarbon groups.

From the viewpoints of exhibiting the liquid crystallinity, adjusting the liquid crystal phase transition temperature, and the availability of raw materials and synthetic suitability and from the viewpoint that the alignment degree of the light absorption anisotropic film is more excellent, a group represented by Formula (M1-A) or Formula (M1-B) is preferable, and a group represented by Formula (M1-B) is more preferable as the mesogen group.

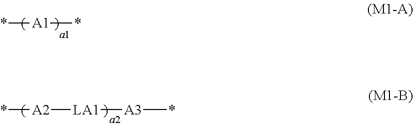

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent.

It is preferable that the divalent group represented by A1 is a 4- to 6-membered ring. Further, the divalent group represented by A1 may be a monocycle or a fused ring.

Further, “*” represents a bonding position with respect to SP1 or T1.

Examples of the divalent aromatic hydrocarbon group represented by A1 include a phenylene group, a naphthylene group, a fluorene-diyl group, an anthracene-diyl group, and a tetracene-diyl group. From the viewpoints of design diversity of a mesogenic skeleton and the availability of raw materials, a phenylene group or a naphthylene group is preferable, and a phenylene group is more preferable.

The divalent heterocyclic group represented by A1 may be any of aromatic or non-aromatic, but a divalent aromatic heterocyclic group is preferable as the divalent heterocyclic group from the viewpoint of further improving the alignment degree.

The atoms other than carbon constituting the divalent aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 represents 2 or greater, a plurality of A1's may be the same as or different from each other.

In Formula (M1-B), A2 and A3 each independently represent a divalent group selected from the group consisting of an aromatic hydrocarbon group, a heterocyclic group, and an alicyclic group. Specific examples and preferred embodiments of A2 and A3 are the same as those for A1 in Formula (M1-A), and thus description thereof will not be repeated.

In Formula (M1-B), a2 represents an integer of 1 to 10. In a case where a2 represents 2 or greater, a plurality of A2's may be the same as or different from each other, a plurality of A3's may be the same as or different from each other, and a plurality of LA1's may be the same as or different from each other. From the viewpoint that the alignment degree of the light absorption anisotropic film is more excellent, a2 represents preferably an integer of 2 or greater and more preferably 2.

In Formula (M1-B), in a case where a2 represents 1, LA1 represents a divalent linking group. In a case where a2 represents 2 or greater, a plurality of LA1's each independently represent a single bond or a divalent linking group, and at least one of the plurality of LA1's is a divalent linking group. In a case where a2 represents 2, from the viewpoint that the alignment degree of the light absorption anisotropic film is more excellent, it is preferable that one of the two LA1's represents a divalent linking group and the other represents a single bond.

In Formula (M1-B), examples of the divalent linking group represented by LA1 include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ each independently represent a hydrogen atom, an alkyl group having 1 to 4 carbon atoms, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—.

Among these, from the viewpoint that the alignment degree of the light absorption anisotropic film is more excellent, —C(O)O— is preferable.

LA1 may represent a group obtained by combining two or more of these groups.

Specific examples of M1 include the following structures. In the following specific example, “Ac” represents an acetyl group.

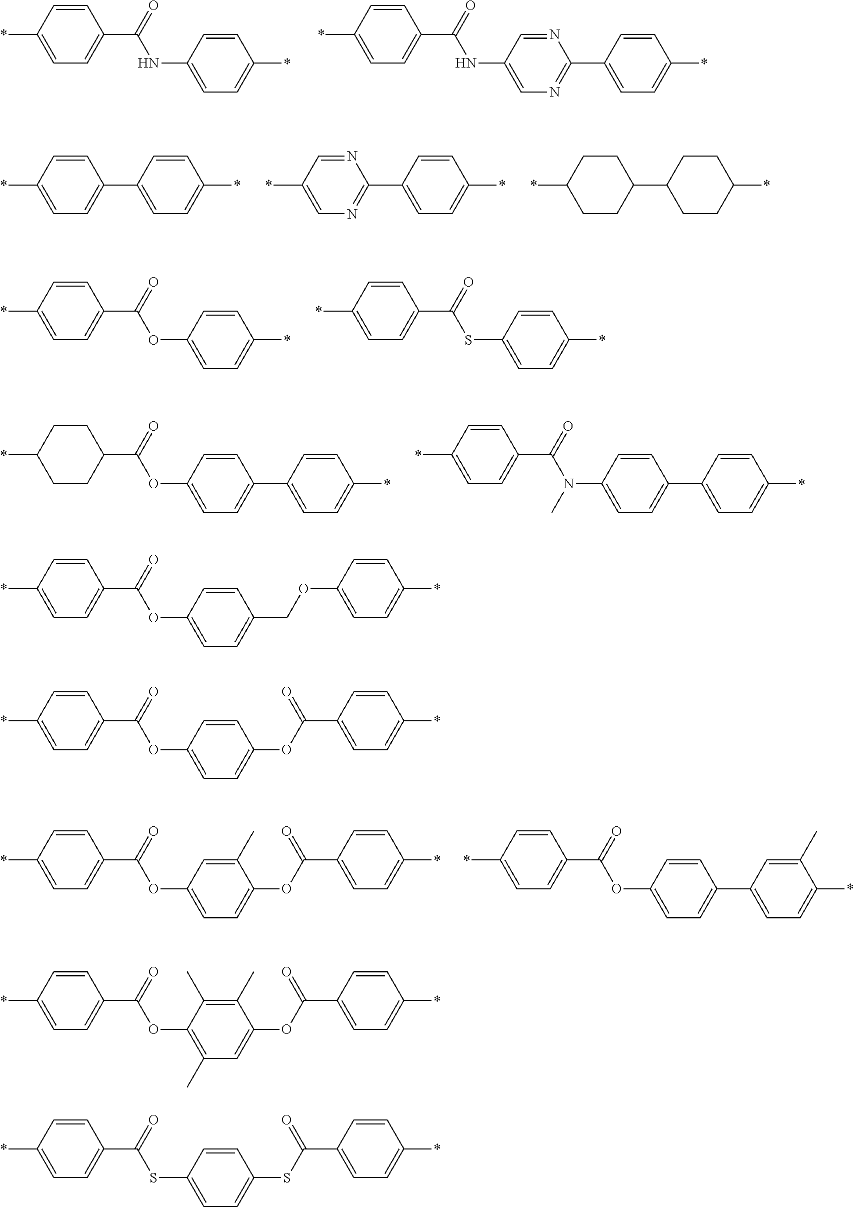

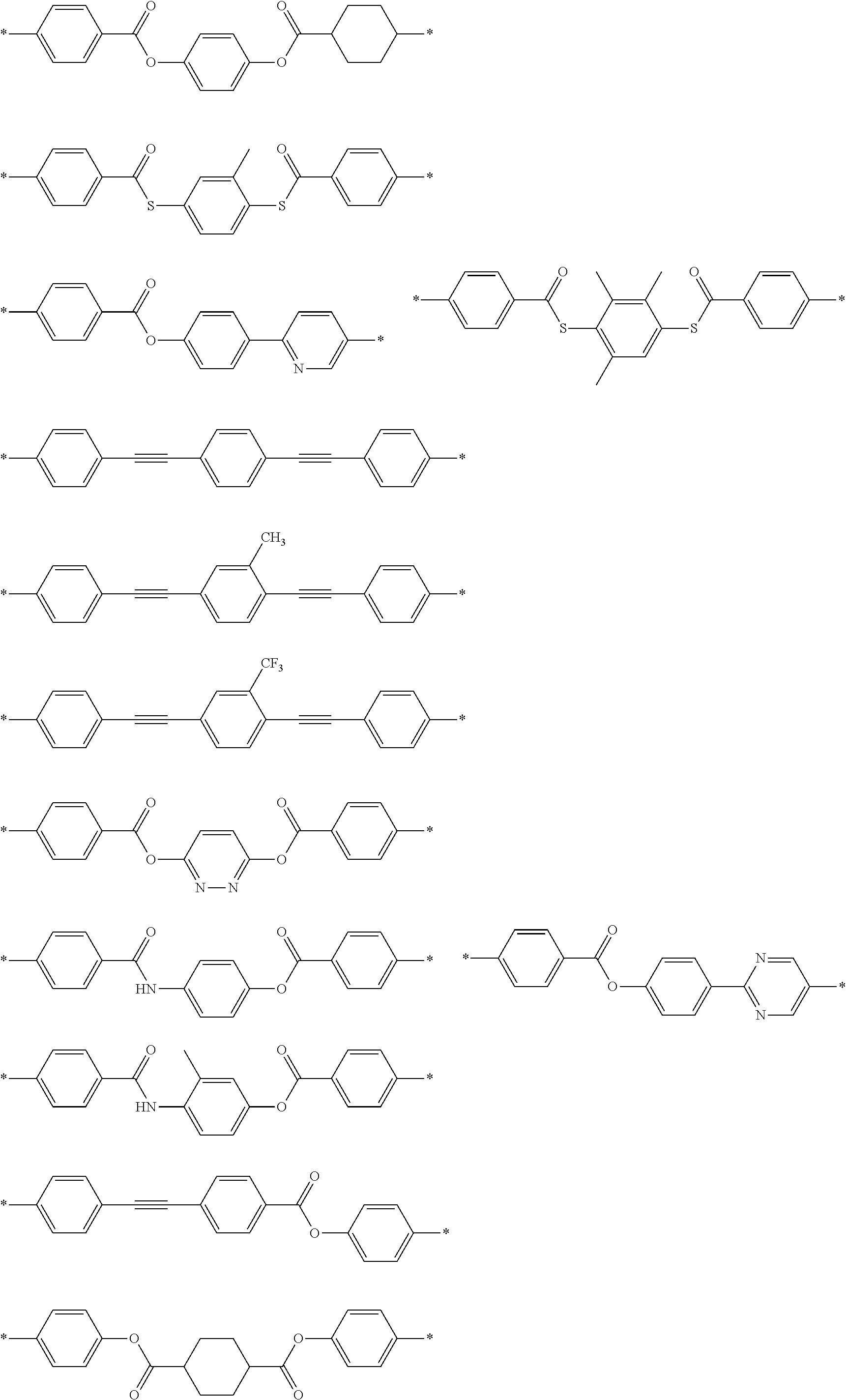

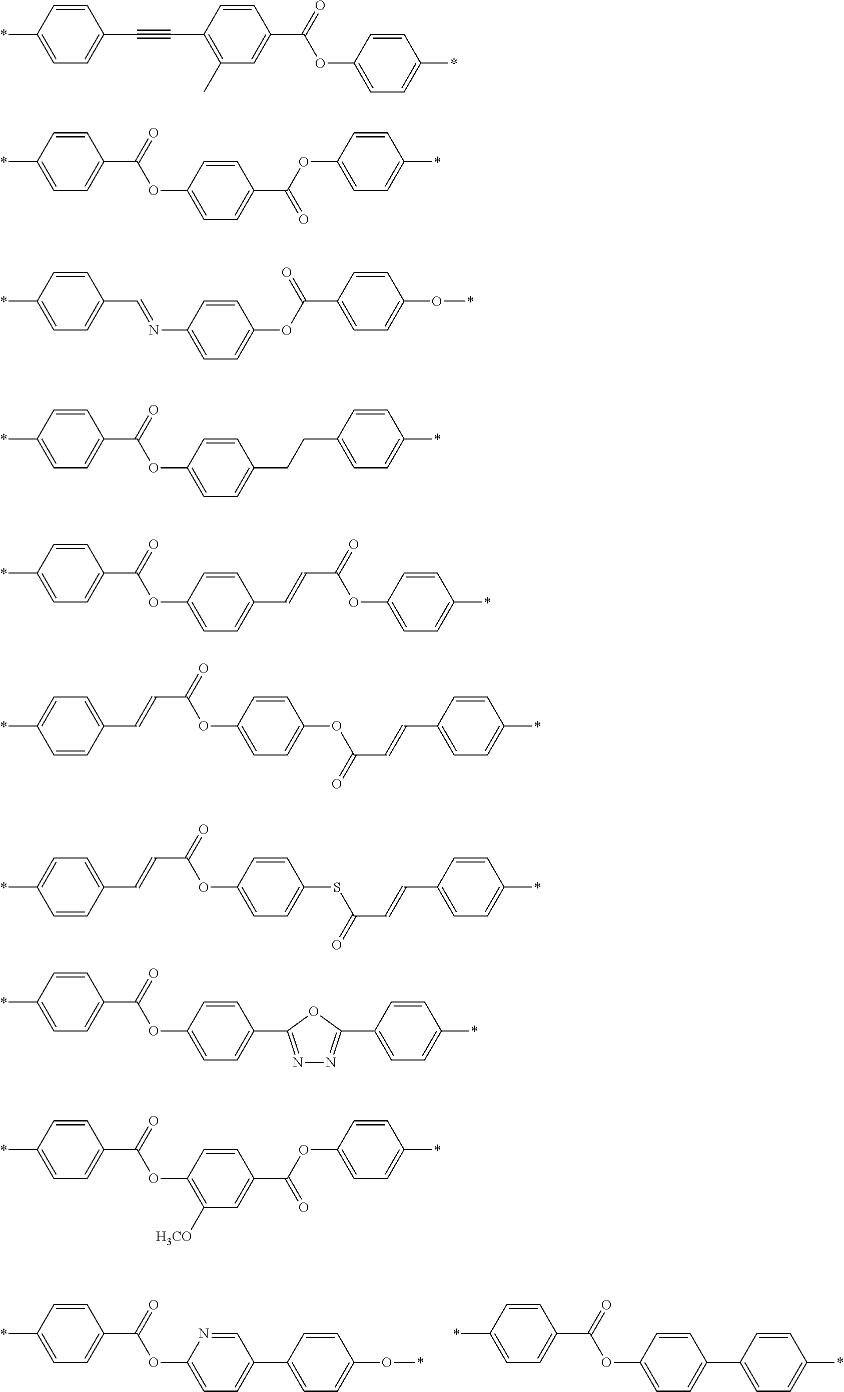

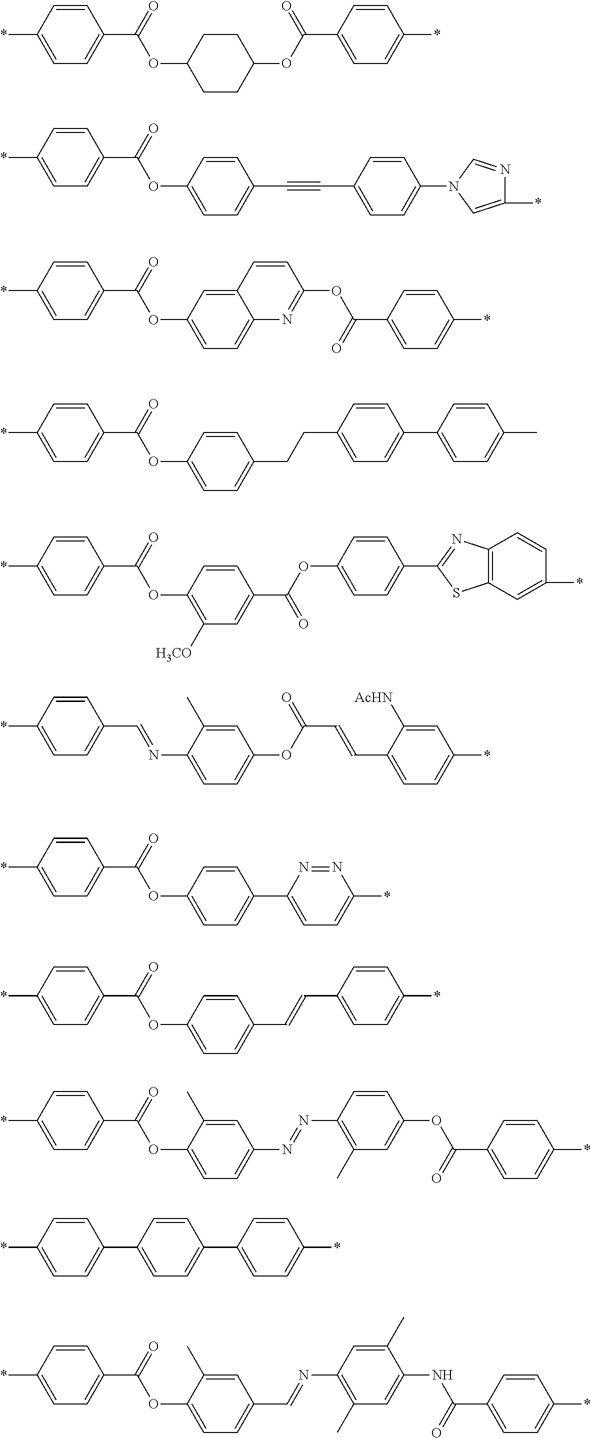

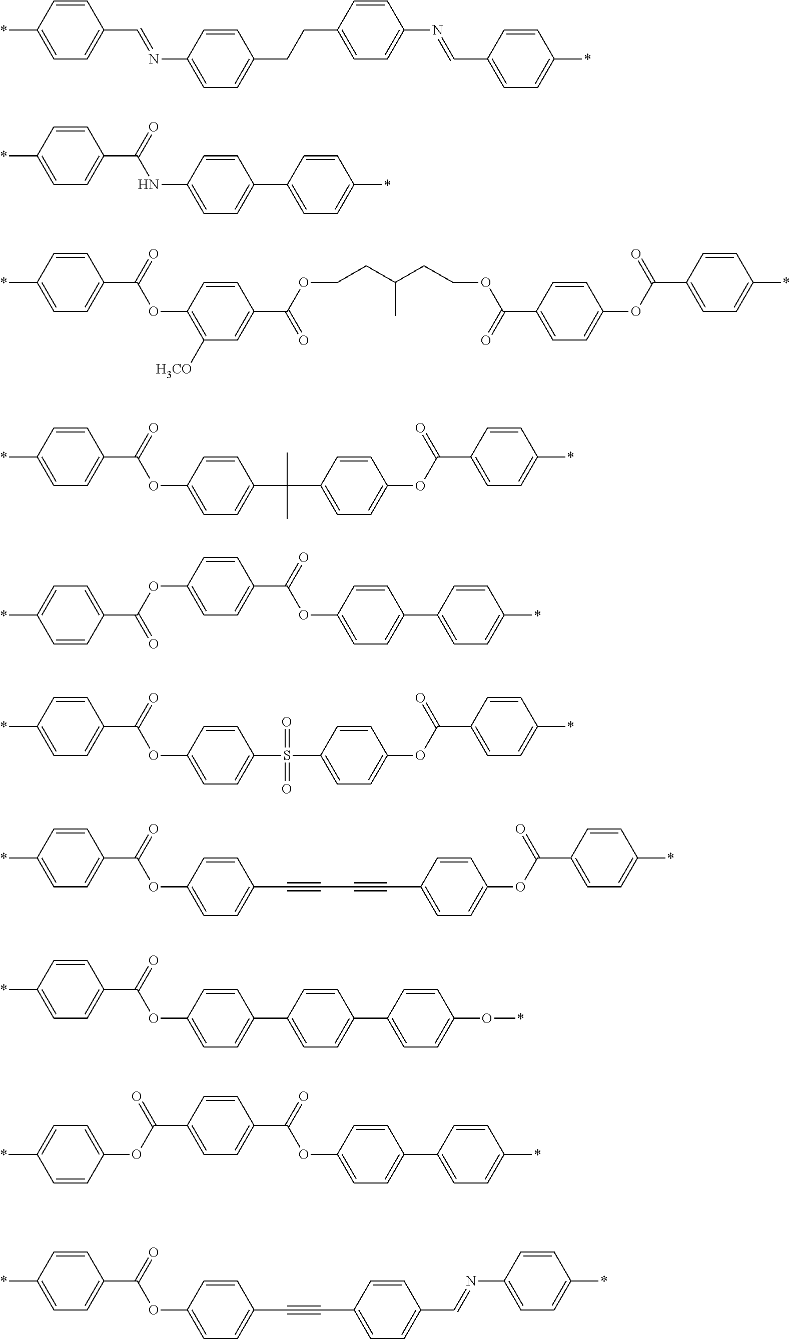

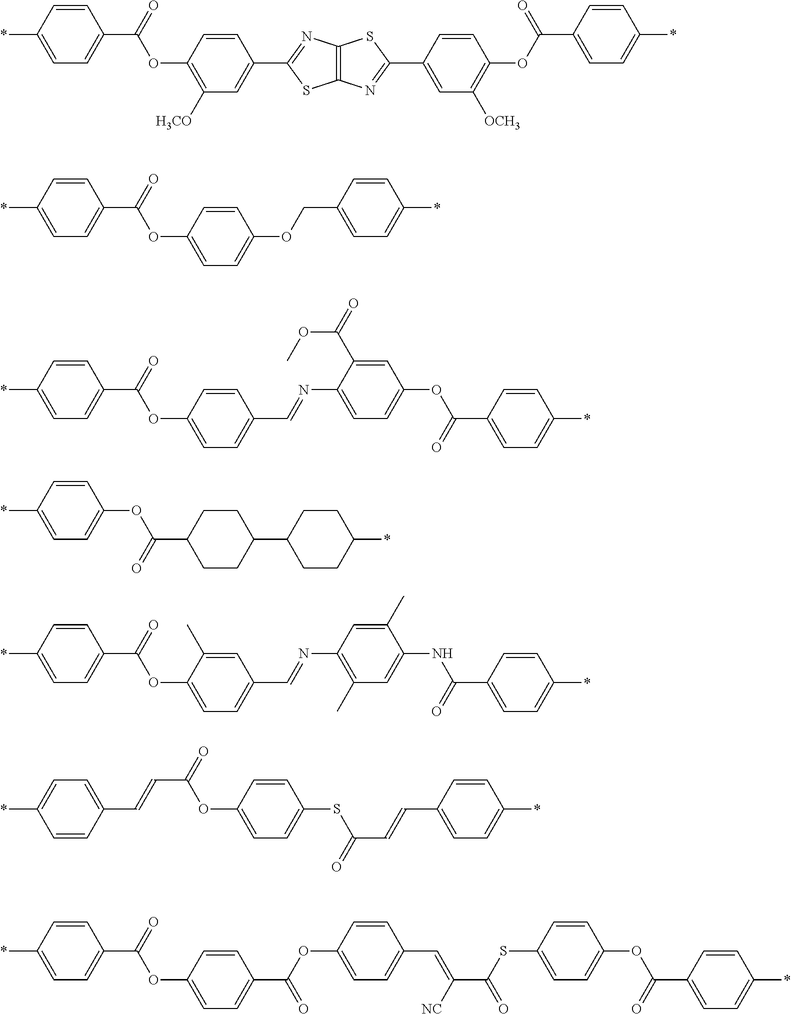

Examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—: R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, and a (meth)acryloyloxy group-containing group. Examples of the (meth)acryloyloxy group-containing group include a group represented by -L-A (L represents a single bond or a linking group, specific examples of the linking group are the same as those for L1 and SP1 described above, and A represents a (meth)acryloyloxy group).

From the viewpoint that the alignment degree of the light absorption anisotropic film is more excellent, T1 represents preferably an alkoxy group having 1 to 10 carbon atoms, more preferably an alkoxy group having 1 to 5 carbon atoms, and still more preferably a methoxy group. These terminal groups may be further substituted with these groups or the polymerizable groups described in JP2010-244038A.

From the viewpoint that the alignment degree of the light absorption anisotropic film is more excellent, the number of atoms in the main chain of T1 is preferably in a range of 1 to 20, more preferably in a range of 1 to 15, still more preferably in a range of 1 to 10, and particularly preferably in a range of 1 to 7. In a case where the number of atoms in the main chain of T1 is 20 or less, the alignment degree of the light absorption anisotropic film is further improved. Here, the “main chain” in T1 indicates the longest molecular chain bonded to M1, and the number of hydrogen atoms is not included in the number of atoms in the main chain of T1. For example, the number of atoms in the main chain is 4 in a case where T1 represents an n-butyl group, the number of atoms in the main chain is 3 in a case where T1 represents a sec-butyl group.

From the viewpoint that the alignment degree of the light absorption anisotropic film is more excellent, the content of the repeating unit (3-1) is preferably in a range of 20% to 100% by mass with respect to 100% by mass of all the repeating units of the polymer liquid crystal compound.

In the present invention, the content of each repeating unit contained in the polymer liquid crystal compound is calculated based on the charged amount (mass) of each monomer used for obtaining each repeating unit.

The polymer liquid crystal compound may have only one or two or more kinds of repeating units (3-1). In a case where the polymer liquid crystal compound has two or more kinds of repeating units (3-1), there is an advantage in that the solubility of the polymer liquid crystal compound in a solvent is improved and the liquid crystal phase transition temperature is easily adjusted. In a case where the polymer liquid crystal compound has two or more kinds of repeating units (3-1), it is preferable that the total amount thereof is in the above-described range.

In a case where the polymer liquid crystal compound has two kinds of the repeating units (3-1), from the viewpoint that the alignment degree of the light absorption anisotropic film is more excellent, it is preferable that the terminal group represented by T1 in one unit (repeating unit A) is an alkoxy group and the terminal group represented by T1 in the other unit (repeating unit B) is a group other than the alkoxy group.

From the viewpoint that the alignment degree of the light absorption anisotropic film is more excellent, as the terminal group represented by T1 in the repeating unit B, an alkoxycarbonyl group, a cyano group, or a (meth)acryloyloxy group-containing group is preferable, and an alkoxycarbonyl group or a cyano group is more preferable.

From the viewpoint that the alignment degree of the light absorption anisotropic film is more excellent, the ratio (AB) of the content of the repeating unit A in the polymer liquid crystal compound to the content of the repeating unit B in the polymer liquid crystal compound is preferably in a range of 50/50 to 95/5, more preferably in a range of 60/40 to 93/7, and still more preferably in a range of 70/30 to 90/10.

<Repeating Unit (3-2)>

The polymer liquid crystal compound of the present invention may further have a repeating unit represented by Formula (3-2) (in the present specification, also referred to as “repeating unit (3-2)”). This provides advantages such as improvement of the solubility of the polymer liquid crystal compound in a solvent and ease of adjustment of the liquid crystal phase transition temperature.

The repeating unit (3-2) is different from the repeating unit (3-1) in terms that the repeating unit (3-2) does not contain at least a mesogen group.

In a case where the polymer liquid crystal compound has the repeating unit (3-2), the polymer liquid crystal compound is a copolymer of the repeating unit (3-1) and the repeating unit (3-2) (or may be a copolymer having the repeating unit A and the repeating unit B) and may be any polymer such as a block polymer, an alternating polymer, a random polymer, or a graft polymer.

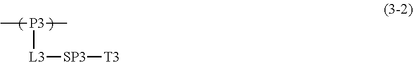

In Formula (3-2), P3 represents the main chain of the repeating unit, L3 represents a single bond or a divalent linking group, SP3 represents a spacer group, and T3 represents a terminal group.

Specific examples of P3, L3, SP3, and T3 in Formula (3-2) are the same as those for P1, L1, SP1, and T1 in Formula (3-1).

Here, from the viewpoint of improving the strength of the light absorption anisotropic film, it is preferable that T3 in Formula (3-2) contains a polymerizable group.

The content of the repeating unit (3-2) is preferably in a range of 0.5% to 40% by mass and more preferably in a range of 1% to 30% by mass with respect to 100% by mass of all the repeating units of the polymer liquid crystal compound.

The polymer liquid crystal compound may have only one or two or more kinds of repeating units (3-2). In a case where the polymer liquid crystal compound has two or more kinds of repeating units (3-2), it is preferable that the total amount thereof is in the above-described ranges.

(Weight-Average Molecular Weight)

From the viewpoint that the alignment degree of the light absorption anisotropic film is more excellent, the weight-average molecular weight (Mw) of the polymer liquid crystal compound is preferably in a range of 1000 to 500000 and more preferably in a range of 2000 to 300000. In a case where the Mw of the polymer liquid crystal compound is in the above-described range, the polymer liquid crystal compound is easily handled.

In particular, from the viewpoint of suppressing cracking during the coating, the weight-average molecular weight (Mw) of the polymer liquid crystal compound is preferably 10000 or greater and more preferably in a range of 10000 to 300000.

In addition, from the viewpoint of the temperature latitude of the alignment degree, the weight-average molecular weight (Mw) of the polymer liquid crystal compound is preferably less than 10000 and more preferably 2000 or greater and less than 10000.

Here, the weight-average molecular weight and the number average molecular weight in the present invention are values measured by the gel permeation chromatography (GPC) method.
Solvent (eluent): N-methylpyrrolidone
Device name: TOSOH HLC-8220GPC
Column: Connect and use three of TOSOH TSKgel Super AWM-H (6 mm×15 cm)
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2800000 to 1050 (Mw/Mn=1.03 to 1.06) are used.

(Content of Liquid Crystal Compound)

The content of the liquid crystal compound is preferably in a range of 30% to 99% by mass, more preferably in a range of 50% to 98% by mass, and particularly preferably in a range of 60% to 95% by mass with respect to the total mass of the solid content of the liquid crystal composition. In a case where the content of the liquid crystal compound is in the above-described ranges, the alignment degree of the light absorption anisotropic film is further improved.

It is preferable that the content of the liquid crystal compound in the light absorption anisotropic film with respect to the total mass of the light absorption anisotropic film is the same as the content of the liquid crystal compound with respect to the total mass of the solid content of the liquid crystal composition described above.

<Dichroic Substance C-1 and Dichroic Substance C-2>

The dichroic substance C-1 is a dichroic substance represented by Formula (C-1), and the dichroic substance C-2 is a dichroic substance represented by Formula (C-2). In the light absorption anisotropic film, the dichroic substance C-1 and the dichroic substance C-2 may be polymerized.

The dichroic substance C-1 and the dichroic substance C-2 may or may not exhibit liquid crystallinity.

In a case where the dichroic substance C-1 and the dichroic substance C-2 exhibit liquid crystallinity, the dichroic substance C-1 and the dichroic substance C-2 may exhibit any of the nematic liquid crystallinity or the smectic liquid crystallinity. The temperature at which the liquid crystal phase is exhibited is preferably in a range of room temperature (approximately 20° C. to 28° C.) to 300° C. and from the viewpoints of handleability and manufacturing suitability, more preferably in a range of 50° C. to 200° C.

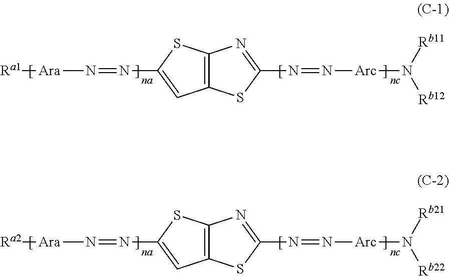

The dichroic substance C-1 and the dichroic substance C-2 are compounds having chemical structures different from each other. Specifically, in Formulae (C-1) and (C-2), in a case where R^{a1} and R^{a2} represent the same group, —N(R^{b11})(R^{b12}) and —N(R^{b21})(R^{b22}) are groups different from each other. Further, in a case where R^{a1} and Rae represent different groups, —N(R^{b11})(R^{b12}) and —N(R^{b21})(R^{b22}) may be groups that are the same as or different from each other.

In Formulae (C-1) and (C-2), the same reference numerals have the same definition. Specifically, Ara and Arc in Formula (C-1) represent the same groups as those for Ara and Arc in Formula (C-2), and na and nc in Formula (C-1) represent the same numerical values as those for na and nc in Formula (C-2).

In Formula (C-1) and Formula (C-2), R^{a1} and R^{a2} each independently represent a hydrogen atom, a monovalent aliphatic hydrocarbon group having 1 to 20 carbon atoms which may have a monovalent substituent, or a monovalent group (hereinafter, also referred to as “monovalent group A1”) in which —CH₂— constituting a monovalent aliphatic hydrocarbon group having 1 to 20 carbon atoms which may have a monovalent substituent is substituted with a divalent substituent. Among these, from the viewpoint that at least one of the alignment degree or the resistance to defects is more excellent, the monovalent group A1 is preferable.

The monovalent aliphatic hydrocarbon group may be saturated or unsaturated, but is preferably saturated. The monovalent aliphatic hydrocarbon group may be linear, branched, or cyclic, but is preferably linear or branched. From the viewpoint that the alignment degree is more excellent, it is preferable that the monovalent aliphatic hydrocarbon group is an alkyl group. The number of carbon atoms of the monovalent aliphatic hydrocarbon group is in a range of 1 to 20, and from the viewpoint that at least one of the alignment degree or the resistance to defects is more excellent, the number thereof is preferably in a range of 5 to 18 and particularly preferably in a range of 10 to 15.

Examples of the monovalent substituent include groups shown in the item of “substituent” described below. Among these, a halogen atom, a hydroxyl group, or a cyano group is preferable.

Specific examples of the divalent substituent include —O—, —C(═O)—, —N(R^{c1})—, —S—, —C(═S)—, —S(═O)—, and a group obtained by combining two or more of these groups. Among these, from the viewpoint that at least one of the alignment degree or the resistance to defects is more excellent, —O—, —C(═O)—, —N(R^{c1})—, or a group obtained by combining two or more of these groups is preferable. Among these, from the viewpoint that at least one of the alignment degree or the resistance to defects is more excellent, a group having an oxygen atom is preferable as the divalent substituent.

R^{c1} represents a hydrogen atom or an alkyl group and preferably a hydrogen atom. The number of carbon atoms of the alkyl group is not particularly limited, but is preferably in a range of 1 to 3 and particularly preferably 1.

In the monovalent group A1, only one —CH₂— constituting a monovalent aliphatic hydrocarbon group may be substituted with a divalent substituent, or two or more of —CH₂—'s may be substituted with a divalent substituent.

Examples of preferred embodiments of the monovalent group A1 include alkyl group-C(═O)—O-alkylene group-O— and alkenyl group-C(═O)—O-alkylene group-O—.

Ara and Arc each independently represent a divalent aromatic group which may have a monovalent substituent and preferably a divalent aromatic group (that is, a divalent aromatic group having no monovalent substituent) from the viewpoint that at least one of the alignment degree or the resistance to defects is more excellent.

Examples of the divalent aromatic group include an arylene group and a heteroarylene group. Among these, from the viewpoint that at least one of the alignment degree or the resistance to defects is more excellent, an arylene group is preferable.

The number of carbon atoms of the arylene group is not particularly limited, but is preferably in a range of 4 to 20 and more preferably in a range of 6 to 12. Specific examples of the arylene group include a phenylene group and a naphthylene group. Among these, from the viewpoint that at least one of the alignment degree or the resistance to defects is more excellent, a phenylene group is preferable.

The number of carbon atoms of the heteroarylene group is not particularly limited, but is preferably in a range of 3 to 10 and more preferably in a range of 3 to 5. Examples of the heteroatom of the heteroaryl group include an oxygen atom, a nitrogen atom, and a sulfur atom.

Examples of the monovalent substituent include groups shown in the item of “substituent” described below. Among these, a halogen atom, a hydroxyl group, or a cyano group is preferable.

R^{b12} represents a monovalent aliphatic hydrocarbon group having 1 to 20 carbon atoms which may have a monovalent substituent or a monovalent group (hereinafter, also referred to as “monovalent group B1”) in which —CH₂— constituting a monovalent aliphatic hydrocarbon group having 1 to 20 carbon atoms which may have a monovalent substituent is substituted with a divalent substituent. Among these, from the viewpoint that at least one of the alignment degree or the resistance to defects is more excellent, the monovalent substituent B1 is preferable.

The monovalent aliphatic hydrocarbon group may be saturated or unsaturated, but is preferably saturated. The monovalent aliphatic hydrocarbon group may be linear, branched, or cyclic, but is preferably linear or branched. From the viewpoint that the alignment degree is more excellent, it is preferable that the monovalent aliphatic hydrocarbon group is an alkyl group. The number of carbon atoms of the monovalent aliphatic hydrocarbon group is in a range of 1 to 20. From the viewpoint that at least one of the alignment degree or the resistance to defects is more excellent, the number of carbon atoms thereof is preferably in a range of 1 to 10 and particularly preferably in a range of 1 to 5.

Examples of the monovalent substituent include groups shown in the item of “substituent” described below. Among these, a hydroxyl group, a halogen atom, a cyano group, or a sulfonic acid group is preferable.

Specific examples of the divalent substituent include —O—, —C(═O)—, —N(R^{c2})—, —S—, —C(═S)—, —S(═O)—, and a group obtained by combining two or more of these groups. Among these, from the viewpoint that at least one of the alignment degree or the resistance to defects is more excellent, —O—, —C(═O)—, —N(R^{c2})—, or a group obtained by combining two or more of these groups is preferable. Among these, from the viewpoint that at least one of the alignment degree or the resistance to defects is more excellent, a group having an oxygen atom is preferable as the divalent substituent.

R^{c2} represents a hydrogen atom or an alkyl group and preferably a hydrogen atom. The number of carbon atoms of the alkyl group is not particularly limited, but is preferably in a range of 1 to 3 and particularly preferably 1.

In the monovalent group B 1, only one —CH₂— constituting a monovalent aliphatic hydrocarbon group may be substituted with a divalent substituent, or two or more of —CH₂—'s may be substituted with a divalent substituent.

Examples of preferred embodiments of the monovalent group B1 include -alkylene group-O—C(═O)-alkyl group, -alkylene group-O—C(═O)-alkenyl group, —C(═O)—O-alkyl group, and -alkylene group-O—C(═O)-alkylene group-monovalent substituent.

R^{b11}, R^{b21}, and R^{b22} each independently represent a hydrogen atom, a monovalent aliphatic hydrocarbon group having 1 to 20 carbon atoms which may have a monovalent substituent, or a monovalent group (hereinafter, also referred to as “monovalent group B2”) in which —CH₂— constituting a monovalent aliphatic hydrocarbon group having 1 to 20 carbon atoms which may have a monovalent substituent is substituted with a divalent substituent.

The monovalent aliphatic hydrocarbon group may be saturated or unsaturated, but is preferably saturated. The monovalent aliphatic hydrocarbon group may be linear, branched, or cyclic, but is preferably linear or branched. From the viewpoint that the alignment degree is more excellent, it is preferable that the monovalent aliphatic hydrocarbon group is an alkyl group. The number of carbon atoms of the monovalent aliphatic hydrocarbon group is in a range of 1 to 20. From the viewpoint that at least one of the alignment degree or the resistance to defects is more excellent, the number of carbon atoms thereof is preferably in a range of 1 to 10 and particularly preferably in a range of 1 to 5.

Examples of the monovalent substituent include groups shown in the item of “substituent” described below. Among these, a hydroxyl group, a halogen atom, a cyano group, or a sulfonic acid group is preferable.

Specific examples of the divalent substituent include —O—, —C(═O)—, —N(R^{c3})—, —S—, —C(═S)—, —S(═O)—, and a group obtained by combining two or more of these groups. Among these, from the viewpoint that at least one of the alignment degree or the resistance to defects is more excellent, —O—, —C(═O)—, —N(R^{c3})—, or a group obtained by combining two or more of these groups is preferable. Among these, from the viewpoint that at least one of the alignment degree or the resistance to defects is more excellent, a group having an oxygen atom is preferable as the divalent substituent.

R^{c3} represents a hydrogen atom or an alkyl group and preferably a hydrogen atom. The number of carbon atoms of the alkyl group is not particularly limited, but is preferably in a range of 1 to 3 and particularly preferably 1.

In the monovalent group B2, only one —CH₂— constituting a monovalent aliphatic hydrocarbon group may be substituted with a divalent substituent, or two or more of —CH₂—'s may be substituted with a divalent substituent.

Examples of preferred embodiments of the monovalent group B2 include -alkylene group-O—C(═O)-alkyl group, -alkylene group-O—C(═O)-alkenyl group, —C(═O)—O-alkyl group, and -alkylene group-O—C(═O)-alkylene group-monovalent substituent.

From the viewpoint that at least one of the alignment degree or the resistance to defects is more excellent, R^{b11} represents preferably a monovalent aliphatic hydrocarbon group having 1 to 20 carbon atoms which may have a monovalent substituent, more preferably a monovalent aliphatic hydrocarbon group having 1 to 20 carbon atoms (that is, a monovalent aliphatic hydrocarbon group having 1 to 20 carbon atoms which does not have a substituent), and still more preferably an alkyl group having 1 to 20 carbon atoms.

From the viewpoint that at least one of the alignment degree or the resistance to defects is more excellent, R^{b21} represents preferably a monovalent aliphatic hydrocarbon group having 1 to 20 carbon atoms which may have a monovalent substituent, more preferably a monovalent aliphatic hydrocarbon group having 1 to 20 carbon atoms (that is, a monovalent aliphatic hydrocarbon group having 1 to 20 carbon atoms which does not have a substituent), and still more preferably an alkyl group having 1 to 20 carbon atoms.

From the viewpoint that at least one of the alignment degree or the resistance to defects is more excellent, it is preferable that R^{b22} represents a monovalent aliphatic hydrocarbon group having 1 to 20 carbon atoms which has a monovalent substituent or the monovalent group B2.

na and nc each independently represent an integer of 0 to 3, preferably an integer of 1 to 3, more preferably an integer of 1 or 2, and particularly preferably 1.

na+nc is 2 or greater, preferably in a range of 2 to 6, more preferably in a range of 2 to 4, and particularly preferably 2.

In a case where the HSP value of R^{b12} is greater than or equal to the HSP value of R^{b11} in Formula (C-1) and the HSP value of R^{b22} is greater than or equal to the HSP value of R^{b21} in Formula (C-2), the absolute value of the difference in the HSP value between R^{b12} in Formula (C-1) and R^{b22} in Formula (C-2) is preferably 3.0 or less, more preferably 1.0 or less, and particularly preferably 0.5 or less. In a case where the absolute value of the difference in the HSP values is 3.0 or less, the occurrence of defects can be further suppressed. Further, the HSP value denotes a Hansen solubility parameter.

From the viewpoint of achieving both a high alignment degree and resistance to defects, the lower limit of the absolute value of the difference in the HSP values is preferably 0 or greater, more preferably 0.1 or greater, and particularly preferably 0.2 or greater.

The HSP value of R^{b11} is preferably in a range of 11.0 to 20.0 and particularly preferably in a range of 13.0 to 17.5.

The HSP value of R^{b12} is preferably in a range of 15.0 to 28.0 and particularly preferably in a range of 16.0 to 27.0.

The HSP value of R^{b21} is preferably in a range of 11.0 to 20.0 and particularly preferably in a range of 13.0 to 17.5.

The HSP value of R^{b22} is preferably in a range of 13.0 to 28.0 and particularly preferably in a range of 14.0 to 27.0.

Here, the details of the Hansen solubility parameter (HSP value) are described in Hansen, Charles (2007), Hansen Solubility Parameters: A user's handbook, Second Edition. Boca Raton, Fla: CRC Press. ISBN 9780849372483. The HSP value of each compound (each group) in the present invention is calculated by inputting the structural formula of the compound into the following software and is, more specifically, a value corresponding to δ total. As the software, Hansen Solubility Parameters in Practice (HSPiP) ver 4.1.07 is used.

Specific examples of the dichroic substance C-1 and the dichroic substance C-2 are shown below, but the present invention is not limited thereto.

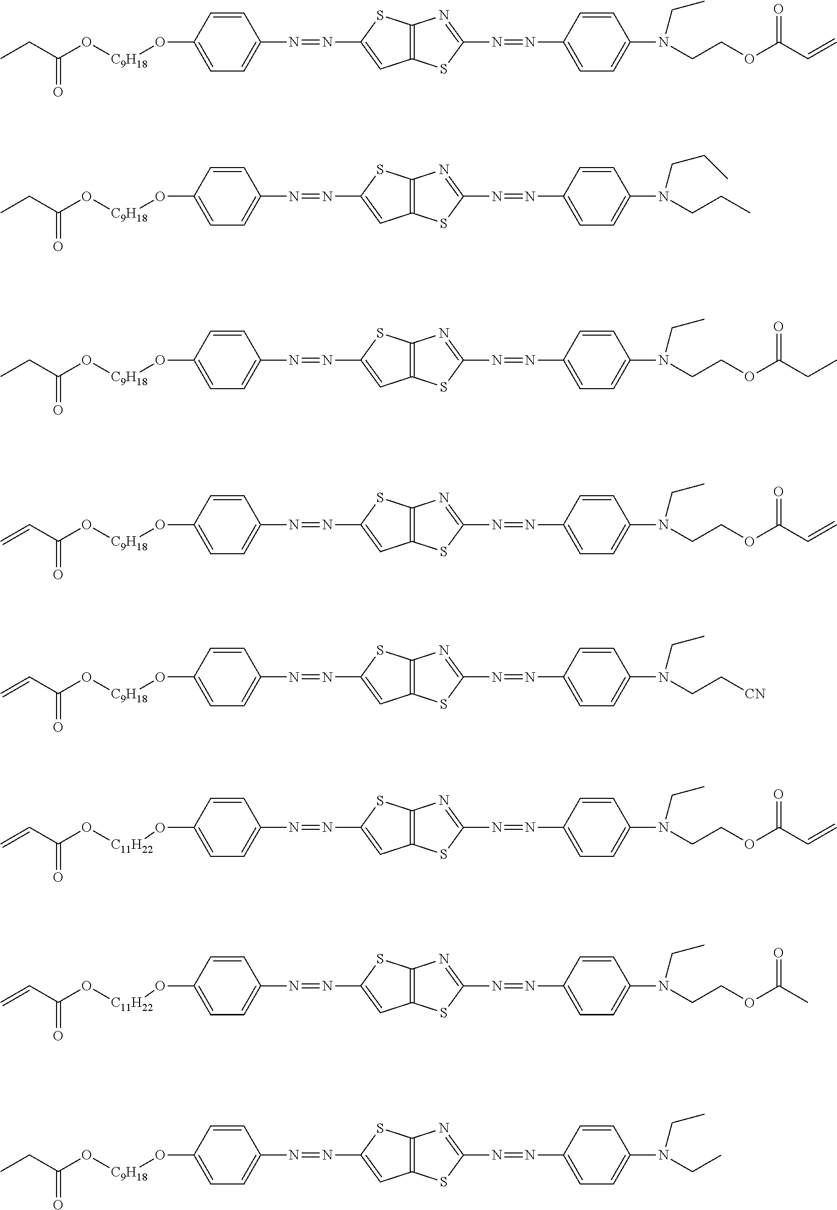

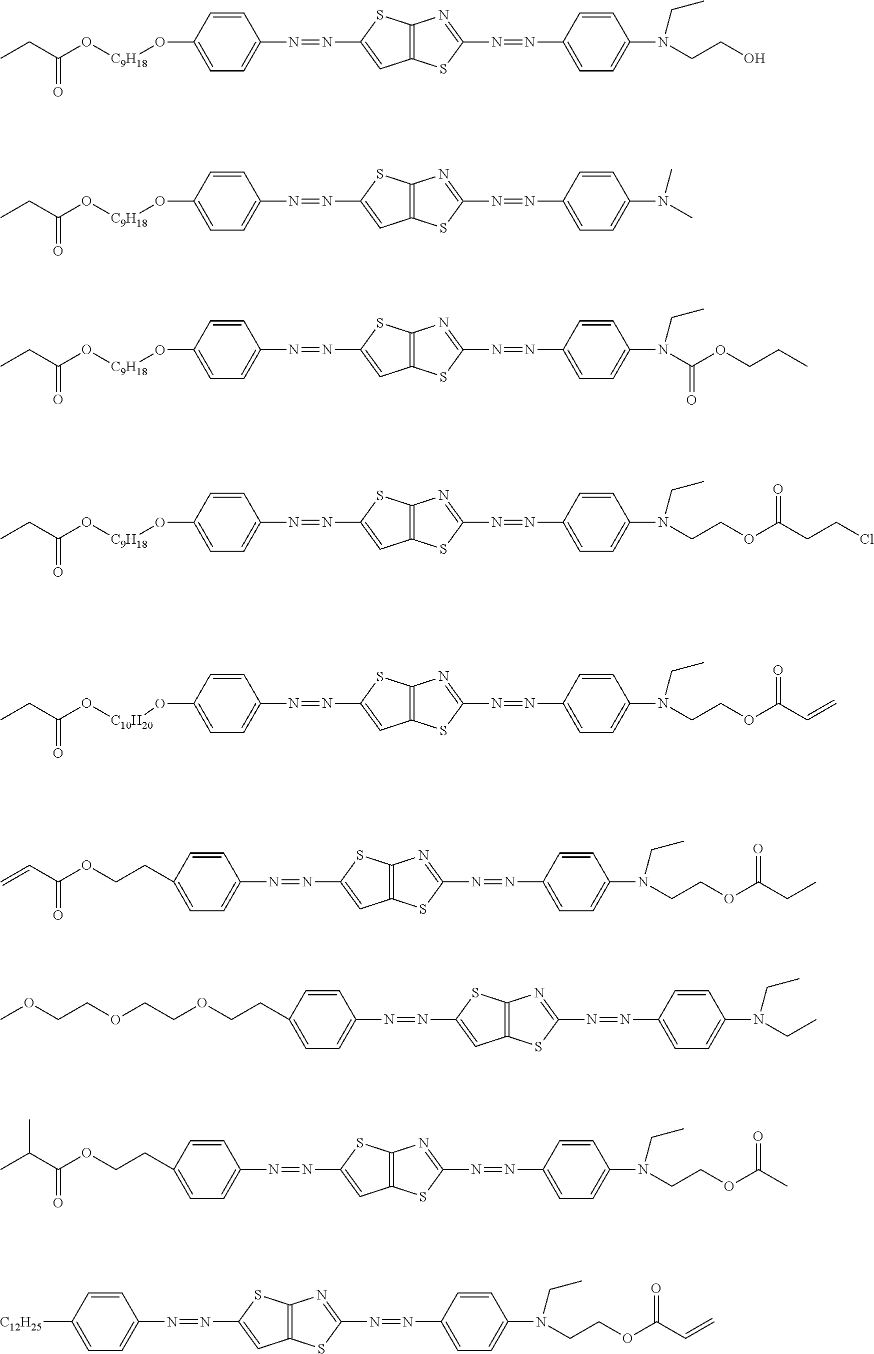

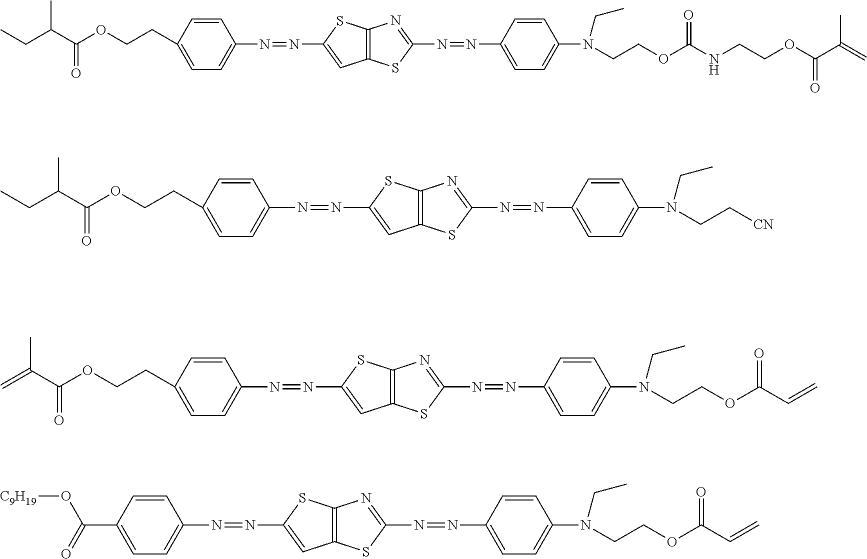

The total content of the dichroic substance C-1 and the dichroic substance C-2 is 4.5% by mass or greater, and from the viewpoint that the alignment degree is more excellent, the total content thereof is preferably 6.5% by mass or greater and particularly preferably 8.0% by mass or greater with respect to the total mass of the solid content of the liquid crystal composition.

From the viewpoint that at least one of the alignment degree or the resistance to defects is more excellent, the total content of the dichroic substance C-1 and the dichroic substance C-2 is preferably 40% by mass or less and particularly preferably 30% by mass or less with respect to the total mass of the solid content of the liquid crystal composition.

It is preferable that the total content of the dichroic substance C-1 and the dichroic substance C-2 with respect to the total mass of the light absorption anisotropic film is the same as the total content of the dichroic substance C-1 and the dichroic substance C-2 with respect to the total mass of the solid content of the liquid crystal composition described above.

From the viewpoint that at least one of the alignment degree or the resistance to defects is more excellent, the mass ratio of the content of the content of the dichroic substance C-1 to the content of the dichroic substance C-2 (content of dichroic substance C-1/content of dichroic substance C-2) in the liquid crystal composition is preferably in a range of 0.100 to 10.0, more preferably in a range of 0.1100 to 4.50, and particularly preferably in a range of 0.100 to 3.5.

It is preferable that the mass ratio of the content of the dichroic substance C-1 to the content of the dichroic substance C-2 in the light absorption anisotropic film is the same as the mass ratio of the content of the dichroic substance C-1 to the content of the dichroic substance C-2 in the liquid crystal composition described above.

<Other Dichroic Substances>

The liquid crystal composition may contain other dichroic substances. The other dichroic substances denote dichroic substances other than the dichroic substance C-1 and the dichroic substance C-2, and specifically, the chemical structures of the other dichroic substances are different from the chemical structures of the dichroic substance C-1 and the dichroic substance C-2.

The other dichroic substances may or may not exhibit liquid crystallinity.

In a case where the other dichroic substances exhibit liquid crystallinity, the dichroic substances may exhibit any of nematic or smectic liquid crystallinity. The temperature at which the liquid crystal phase is exhibited is preferably in a range of room temperature (approximately 20° C. to 28° C.) to 300° C. and from the viewpoints of handleability and manufacturing suitability, more preferably in a range of 50° C. to 200° C.

The other dichroic substances may be used alone or in combination of two or more kinds thereof.

The other dichroic substances are not particularly limited, and examples thereof include a visible light absorbing material (dichroic coloring agent), a light emitting material (such as a fluorescent material or a phosphorescent material), an ultraviolet absorbing material, an infrared absorbing material, a non-linear optical material, a carbon nanotube, and an inorganic material (for example, a quantum rod). Further, known dichroic substances (dichroic coloring agents) of the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, and paragraphs [0014] to [0034] of WO2018/164252A.

In a case where the liquid crystal composition contains other dichroic substances, the content of the other dichroic substances is preferably in a range of 0.2% to 20.0% by mass and particularly preferably in a range of 0.5% to 15.0% by mass with respect to the total mass of the solid content of the liquid crystal composition.

In a case where the light absorption anisotropic film contains other dichroic substances, it is preferable that the content of the other dichroic substances in the light absorption anisotropic film with respect to the total mass of the light absorption anisotropic film is the same as the content of the other dichroic substances with respect to the total mass of the solid content of the liquid crystal composition described above.

The light absorption anisotropic film according to the embodiment of the present invention may have an arrangement structure formed of a dichroic substance. Examples of the dichroic substance forming the arrangement structure include the dichroic substance represented by Formula (C-1), the dichroic substance represented by Formula (C-2), and the other dichroic substances. Among these dichroic substances, the dichroic substance forming the arrangement structure may be used alone or in combination of a plurality of kinds thereof. In a case where the light absorption anisotropic film contains a plurality of dichroic substances, all kinds of dichroic substances to be contained may form the arrangement structure, or some kinds of dichroic substances may form the arrangement structure.

Further, the arrangement structure may be an arrangement structure consisting of one dichroic substance or an arrangement structure consisting of a plurality of dichroic substances.

The light absorption anisotropic film may have a plurality of different arrangement structures. In a case where the light absorption anisotropic film contains a plurality of dichroic substances forming the arrangement structure, the dichroic substances forming the arrangement structure may be the same as or different from each other.

<Solvent>

From the viewpoint of workability and the like, it is preferable that the liquid crystal composition contains a solvent.

Examples of the solvent include organic solvents such as ketones (such as acetone, 2-butanone, methyl isobutyl ketone, cyclopentanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, it is preferable to use an organic solvent and more preferable to use halogenated carbons or ketones from the viewpoint that the effects of the present invention are more excellent.

In a case where the liquid crystal composition contains a solvent, the content of the solvent is preferably in a range of 80% to 99% by mass, more preferably in a range of 83% to 97% by mass, and particularly preferably in a range of 85% to 95% by mass with respect to the total mass of the liquid crystal composition.

<Polymerization Initiator>

It is preferable that the liquid crystal composition contains a polymerization initiator.

It is preferable that the polymerization initiator to be used is a photopolymerization initiator capable of initiating a polymerization reaction by irradiation with ultraviolet rays.

Examples of the photopolymerization initiator include α-carbonyl compounds (described in the specifications of U.S. Pat. Nos. 2,367,661A and 2,367,670A), acyloin ether (described in the specification of U.S. Pat. No. 2,448,828A), α-hydrocarbon-substituted aromatic acyloin compounds (described in the specification of U.S. Pat. No. 2,722,512A), polynuclear quinone compounds (described in the specifications of U.S. Pat. Nos. 3,046,127A and 2,951,758A), a combination of a triarylimidazole dimer and a p-aminophenyl ketone (described in the specification of U.S. Pat. No. 3,549,367A), acridine and phenazine compounds (described in the specifications of JP1985-105667A (JP-S60-105667A) and U.S. Pat. No. 4,239,850A), oxadiazole compounds (described in the specification of U.S. Pat. No. 4,212,970A), and acylphosphine oxide compounds (described in JP1988-40799B (JP-S63-40799B), JP1993-29234B (JP-H5-29234B), JP1998-95788A (JP-H10-95788A), and JP1998-29997A (JP-H10-29997A)).

Further, in the present invention, it is also preferable that the polymerization initiator is an oxime-type polymerization initiator, and specific examples thereof include the initiators described in paragraphs [0049] to [0052] of WO2017/170443A.

The polymerization initiator may be used alone or in combination of two or more kinds thereof.

In a case where the liquid crystal composition contains a polymerization initiator, the content of the polymerization initiator is preferably in a range of 0.01 to 30 parts by mass and more preferably in a range of 0.1 to 15 parts by mass with respect to 100 parts by mass of the total amount of the dichroic substances (that is, the total amount of the dichroic substance C-1, the dichroic substance C-2, and other dichroic substances to be used as necessary) and the liquid crystal compound. The durability of the light absorption anisotropic film is enhanced in a case where the content of the polymerization initiator is 0.01 parts by mass or greater, and the alignment degree of the light absorption anisotropic film is enhanced in a case where the content thereof is 30 parts by mass or less.

<Interface Improver>

It is preferable that the liquid crystal composition contains an interface improver. In a case where the liquid crystal composition contains an interface improver, the smoothness of the coated surface is improved, the alignment degree is improved, and cissing and unevenness are suppressed so that the in-plane uniformity is expected to be improved.

Further, fluorine (meth)acrylate-based polymers described in [0018] to [0043] of JP2007-272185A can also be used as the interface improver. Compounds other than the compounds described above may be used as the interface improver. The interface improver may be used alone or in combination of two or more kinds thereof.

In a case where the liquid crystal composition contains an interface improver, the content of the interface improver in the liquid crystal composition is preferably in a range of 0.1% to 2.0% by mass and more preferably in a range of 0.1% to 1.0% by mass with respect to the total mass of the solid content of the liquid crystal composition.

In a case where the light absorption anisotropic film contains an interface improver, it is preferable that the content of the interface improver with respect to the total mass of the light absorption anisotropic film is the same as the content of the interface improver with respect to the total mass of the solid content of the liquid crystal composition.

<Vertical Alignment Agent>

From the viewpoint that the liquid crystal compound and the dichroic substance are easily vertically aligned, it is preferable that the liquid crystal composition contains a vertical alignment agent.

Examples of the vertical alignment agent include a boronic acid compound and an onium salt. The vertical alignment agent may be used alone or in combination of two or more kinds thereof.

As the boronic acid compound, a compound represented by Formula (30) is preferable.

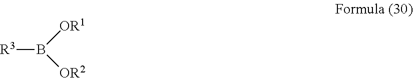

In Formula (30), R¹ and R² each independently represent a hydrogen atom, a substituted or unsubstituted aliphatic hydrocarbon group, a substituted or unsubstituted aryl group, or a substituted or unsubstituted heterocyclic group.

R³ represents a substituent containing a (meth)acrylic group.

Specific examples of the boronic acid compound include a boronic acid compound represented by General Formula (I) described in paragraphs [0023] to [0032] of JP2008-225281A.

As the boronic acid compound, compounds shown below are also preferable.

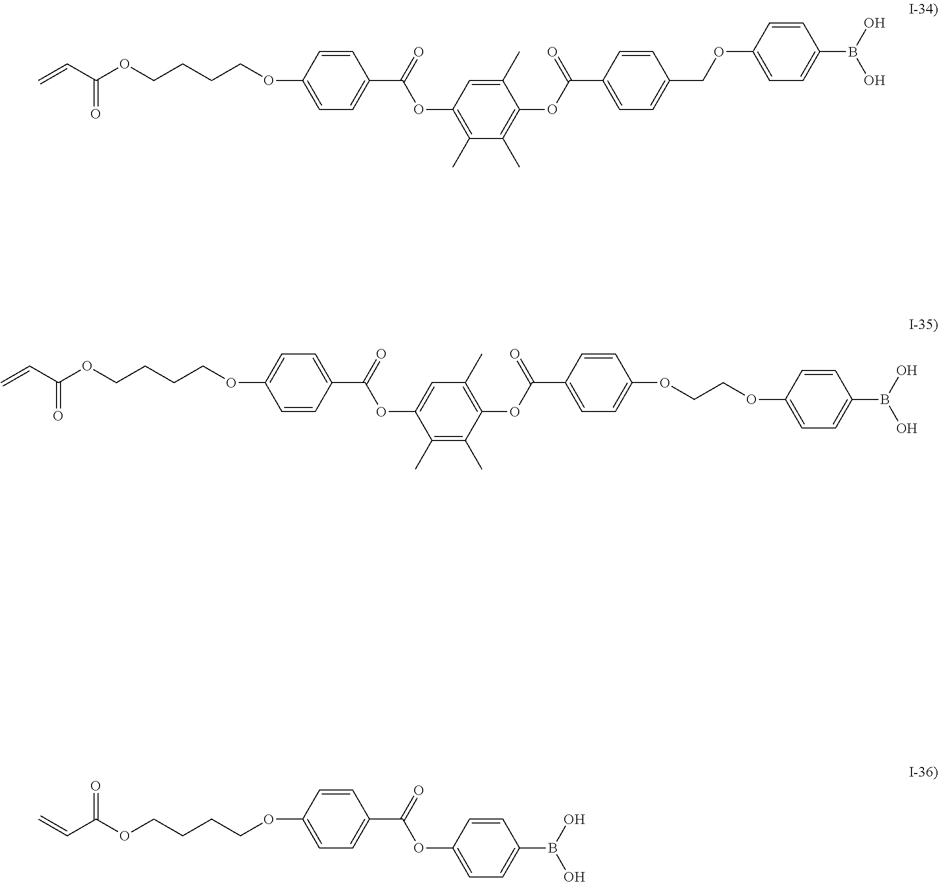 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

As the onium salt, a compound represented by Formula (31) is preferable.

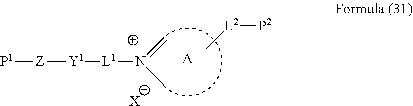

In Formula (31), the ring A represents a quaternary ammonium ion consisting of a nitrogen-containing heterocyclic ring. X represents an anion. L1 represents a divalent linking group. L2 represents a single bond or a divalent linking group. Y¹ represents a divalent linking group having a 5- or 6-membered ring as a partial structure. Further, Z represents a divalent linking group containing an alkylene group having 2 to 20 carbon atoms as a partial structure. P1 and P2 each independently represent a monovalent substituent having a polymerizable ethylenically unsaturated bond.

Specific examples of the onium salt include the onium salts described in paragraphs 0052 to 0058 of JP2012-208397A, the onium salts described in paragraphs 0024 to 0055 of JP2008-026730A, and the onium salts described in JP2002-37777A.

In a case where the liquid crystal composition contains a vertical alignment agent, the content of the vertical alignment agent in the liquid crystal composition is preferably in a range of 0.05% to 7.0% by mass and more preferably in a range of 0.1% to 5.0% by mass with respect to the total mass of the solid content of the liquid crystal composition.

In a case where the light absorption anisotropic film contains the vertical alignment agent, it is preferable that the content of the vertical alignment agent with respect to the total mass of the light absorption anisotropic film is the same as the content of the vertical alignment agent with respect to the total mass of the solid content of the liquid crystal composition.

<Additive>

The liquid crystal composition may contain components other than the components described above. Examples of such components include additives such as a leveling agent, a polymerizable component, and a durability improver.

<Substituent>

The substituent (monovalent substituent) in the present specification denotes the following groups unless otherwise specified.

Examples of the substituent include an alkyl group (preferably an alkyl group having 1 to 20 carbon atoms, more preferably an alkyl group having 1 to 12 carbon atoms, and particularly preferably an alkyl group having 1 to 8 carbon atoms, and examples thereof a methyl group, an ethyl group, an isopropyl group, a tert-butyl group, an n-octyl group, an n-decyl group, an n-hexadecyl group, a cyclopropyl group, a cyclopentyl group, and a cyclohexyl group), an alkenyl group (preferably an alkenyl group having 2 to 20 carbon atoms, more preferably an alkenyl group having 2 to 12 carbon atoms, and particularly preferably an alkenyl group having 2 to 8 carbon atoms, and examples thereof include a vinyl group, an aryl group, a 2-butenyl group, and a 3-pentenyl group), an alkynyl group (preferably an alkynyl group having 2 to 20 carbon atoms, more preferably an alkynyl group 2 to 12 carbon atoms, and particularly preferably an alkynyl group having 2 to 8 carbon atoms, and examples thereof include a propargyl group and a 3-pentynyl group), an aryl group (preferably an aryl group having 6 to 30 carbon atoms, more preferably an aryl group having 6 to 20 carbon atoms, and particularly preferably an aryl group having 6 to 12 carbon atoms, and examples thereof include a phenyl group, a 2,6-diethylphenyl group, a 3,5-ditrifluoromethylphenyl group, a styryl group, a naphthyl group, and a biphenyl group), a substituted or unsubstituted amino group (preferably an amino group having 0 to 20 carbon atoms, more preferably an amino group having 0 to 10 carbon atoms, and particularly preferably an amino group having 0 to 6 carbon atoms, and examples thereof include an unsubstituted amino group, a methylamino group, a dimethylamino group, a diethylamino group, and an anilino group), an alkoxy group (preferably an alkoxy group having 1 to 20 carbon atoms and more preferably an alkoxy group having 1 to 15 carbon atoms, and examples thereof include a methoxy group, an ethoxy group, and a butoxy group), an oxycarbonyl group (preferably an oxycarbonyl group having 2 to 20 carbon atoms, more preferably an oxycarbonyl group having 2 to 15 carbon atoms, and particularly preferably an oxycarbonyl group having 2 to 10 carbon atoms, and examples thereof include a methoxycarbonyl group, an ethoxycarbonyl group, and a phenoxycarbonyl group), an acyloxy group (preferably an acyloxy group having 2 to 20 carbon atoms, more preferably an acyloxy group having 2 to 10 carbon atoms, and particularly preferably an acyloxy group having 2 to 6 carbon atoms, and examples thereof include an acetoxy group, a benzoyloxy group, an acryloyl group, and a methacryloyl group), an acylamino group (preferably an acylamino group having 2 to 20 carbon atoms, more preferably an acylamino group having 2 to 10 carbon atoms, and particularly preferably an acylamino group having 2 to 6 carbon atoms, and examples thereof include an acetylamino group and a benzoylamino group), an alkoxycarbonylamino group (preferably an alkoxycarbonylamino group having 2 to 20 carbon atoms, more preferably an alkoxycarbonylamino group having 2 to 10 carbon atoms, and particularly preferably an alkoxycarbonylamino group having 2 to 6 carbon atoms, and examples thereof include a methoxycarbonylamino group), an aryloxycarbonylamino group (preferably an aryloxycarbonylamino group having 7 to 20 carbon atoms, more preferably an aryloxycarbonylamino group having 7 to 16 carbon atoms, and particularly preferably an aryloxycarbonylamino group having 7 to 12 carbon atoms, and examples thereof include a phenyloxycarbonylamino group), a sulfonylamino group (preferably a sulfonylamino group having 1 to 20 carbon atoms, more preferably a sulfonylamino group having 1 to 10 carbon atoms, and particularly preferably a sulfonylamino group having 1 to 6 carbon atoms, and examples thereof include a methanesulfonylamino group and a benzenesulfonylamino group), a sulfamoyl group (preferably a sulfamoyl group having 0 to 20 carbon atoms, more preferably a sulfamoyl group having 0 to 10 carbon atoms, and particularly preferably a sulfamoyl group having 0 to 6 carbon atoms, and examples thereof include a sulfamoyl group, a methyl sulfamoyl group, a dimethylsulfamoyl group, and a phenylsulfamoyl group), a carbamoyl group (preferably a carbamoyl group having 1 to 20 carbon atoms, more preferably a carbamoyl group having 1 to 10 carbon atoms, and particularly preferably a carbamoyl group having 1 to 6 carbon atoms, and examples thereof include an unsubstituted carbamoyl group, a methylcarbamoyl group, a diethylcarbamoyl group, and a phenylcarbamoyl group), an alkylthio group (preferably an alkylthio group having 1 to 20 carbon atoms, more preferably an alkylthio group having 1 to 10 carbon atoms, and particularly preferably an alkylthio group having 1 to 6 carbon atoms, and examples thereof include a methylthio group and an ethylthio group), an arylthio group (preferably an arylthio group having 6 to 20 carbon atoms, more preferably an arylthio group having 6 to 16 carbon atoms, and particularly preferably an arylthio group having 6 to 12 carbon atoms, and examples thereof include a phenylthio group), a sulfonyl group (preferably a sulfonyl group having 1 to 20 carbon atoms, more preferably a sulfonyl group having 1 to 10 carbon atoms, and particularly preferably a sulfonyl group having 1 to 6 carbon atoms, and examples thereof include a mesyl group and a tosyl group), a sulfinyl group (preferably a sulfinyl group having 1 to 20 carbon atoms, more preferably a sulfinyl group having 1 to 10 carbon atoms, and particularly preferably a sulfinyl group having 1 to 6 carbon atoms, and examples thereof include a methanesulfinyl group and a benzenesulfinyl group), a ureido group (preferably a ureido group having 1 to 20 carbon atoms, more preferably a ureido group having 1 to 10 carbon atoms, and particularly preferably a ureido group having 1 to 6 carbon atoms, and examples thereof include an unsubstituted ureido group, a methylureido group, and a phenylureido group), a phosphoric acid amide group (preferably a phosphoric acid amide group having 1 to 20 carbon atoms, more preferably a phosphoric acid amide group having 1 to 10 carbon atoms, and particularly preferably a phosphoric acid amide group having 1 to 6 carbon atoms, and examples thereof include a diethylphosphoric acid amide group and a phenylphosphoric acid amide group), a hydroxy group, a mercapto group, a halogen atom (such as a fluorine atom, a chlorine atom, a bromine atom, and an iodine atom), a cyano group, a nitro group, a hydroxamic acid group, a sulfino group, a hydrazino group, an imino group, an azo group, a heterocyclic group (preferably a heterocyclic group having 1 to 30 carbon atoms and more preferably a heterocyclic group having 1 to 12 carbon atoms, and examples thereof include a heterocyclic group having a heteroatom such as a nitrogen atom, an oxygen atom, or a sulfur atom, and examples of the heterocyclic group having a heteroatom include an epoxy group, an oxetanyl group, an imidazolyl group, a pyridyl group, a quinolyl group, a furyl group, a piperidyl group, a morpholino group, a maleimide group, a benzoxazolyl group, a benzimidazolyl group, and a benzothiazolyl group), a silyl group (preferably a silyl group having 3 to 40 carbon atoms, more preferably a silyl group having 3 to 30 carbon atoms, and particularly preferably a silyl group having 3 to 24 carbon atoms, and examples thereof include a trimethylsilyl group and a triphenylsilyl group), a carboxy group, a sulfonic acid group, and a phosphoric acid group.

[Vertical Alignment]

As described above, in the light absorption anisotropic film according to the embodiment of the present invention, the liquid crystal compound is vertically aligned. Further, in the light absorption anisotropic film according to the embodiment of the present invention, it is preferable that the dichroic substance is also vertically aligned along the liquid crystal compound.

Here, the vertical alignment denotes that a molecular axis of the liquid crystal compound (for example, a major axis corresponds to the molecular axis in a case of a rod-like liquid crystal compound) is vertical to the main surface of the light absorption anisotropic film, but the axis is not required to be strictly vertical to the surface, and the tilt angle between an average molecular axis of the liquid crystal compound in the light absorption anisotropic film and the main surface of the light absorption anisotropic film is less than 90°±10°. Further, the tilt angle can be measured using AxoScan OPMF-1 (manufactured by Opto Science, Inc.).

Specifically, an extinction coefficient ko [λ] (in-plane direction) and an extinction coefficient ke [λ] (thickness direction) are calculated using AxoScan OPMF-1 (manufactured by Opto science, Inc.) by measuring the Mueller matrix of the light absorption anisotropic film at a wavelength λ and at room temperature while the polar angle is changed from −50° to 50° by 10°, removing the influence of the surface reflection, and fitting the result to the following theoretical formula in consideration of the Snell's formula and Fresnel's equations. Unless otherwise specified, the wavelength λ is 550 nm.

k=−log (T)×λ/(4πd)

Here, T represents the transmittance, and d represents the thickness of the light absorption anisotropic film.

By calculating the absorbance and the dichroic ratio in the in-plane direction and the thickness direction based on the calculated ko [λ] and ke [λ], it can be confirmed whether the liquid crystal compound and the dichroic substance are vertically aligned.

[Method of Producing Light Absorption Anisotropic Film]

The method of producing the light absorption anisotropic film according to the embodiment of the present invention is not particularly limited, but a method of sequentially performing a step of coating an alignment film with the above-described liquid crystal composition to form a coating film (hereinafter, also referred to as “coating film forming step”) and a step of aligning liquid crystal components contained in the coating film (hereinafter, also referred to as “aligning step”) in this order (hereinafter, also referred to as “present production method”) is preferable from the viewpoint that the alignment degree of the light absorption anisotropic film to be obtained is further increased.

Further, the liquid crystal component is a component that contains not only the liquid crystal compound described above but also a dichroic substance having liquid crystallinity.

Hereinafter, each step will be described.

<Coating Film Forming Step>

The coating film forming step is a step of coating the alignment film with the above-described liquid crystal composition to form a coating film. The liquid crystal compound in the coating film is vertically aligned due to an interaction between the alignment film and the vertical alignment agent (in a case where the liquid crystal composition contains a vertical alignment agent).

The alignment film is easily coated with the liquid crystal composition by using the liquid crystal composition containing the above-described solvent or using a liquid-like material such as a melt obtained by heating the liquid crystal composition.

Examples of the method of coating the base material with the liquid crystal composition include known methods such as a roll coating method, a gravure printing method, a spin coating method, a wire bar coating method, an extrusion coating method, a direct gravure coating method, a reverse gravure coating method, a die coating method, a spraying method, and an ink jet method.

(Alignment Film)

An alignment film may be any film as long as the film allows the liquid crystal compound contained in the liquid crystal composition to be vertically aligned.

An alignment film can be provided by means such as a rubbing treatment performed on a film surface of an organic compound (preferably a polymer), oblique vapor deposition of an inorganic compound, formation of a layer having microgrooves, or accumulation of an organic compound (such as w-tricosanoic acid, dioctadecylmethylammonium chloride, or methyl stearylate) using a Langmuir-Blodgett method (LB film). Further, an alignment film in which an alignment function is generated by application of an electric field, application of a magnetic field, or irradiation with light is also known. Among these, in the present invention, an alignment film formed by performing a rubbing treatment is preferable from the viewpoint of easily controlling the pretilt angle of the alignment film, and a photo-alignment film formed by irradiation with light is also preferable from the viewpoint of the uniformity of alignment.

(1) Rubbing Treatment Alignment Film

A polymer material used for the alignment film formed by performing a rubbing treatment is described in a plurality of documents, and a plurality of commercially available products can be used. In the present invention, polyvinyl alcohol or polyimide and derivatives thereof are preferably used. The alignment film can refer to the description on page 43, line 24 to page 49, line 8 of WO2001/88574A1. The thickness of the alignment film is preferably in a range of 0.01 to 10 μm and more preferably in a range of 0.01 to 1 μm.

(2) Photo-Alignment Film

A photo-alignment material used for an alignment film formed by irradiation with light is described in a plurality of documents. In the present invention, preferred examples thereof include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B, aromatic ester compounds described in JP2002-229039A, maleimide and/or alkenyl-substituted nadiimide compounds having a photo-alignment unit described in JP2002-265541A and JP2002-317013A, photocrosslinkable silane derivatives described in JP4205195B and JP4205198B, and photocrosslinkable polyimides, polyamides, or esters described in JP2003-520878A, JP2004-529220A, and JP4162850B. Among these, the azo compounds, the photocrosslinkable polyimides, the polyamides, or the esters are more preferable.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photoreaction in the photo-alignment material. The wavelength of the light to be used varies depending on the photo-alignment material to be used and is not particularly limited as long as the wavelength is required for the photoreaction. The peak wavelength of light to be used for irradiation with light is preferably in a range of 200 nm to 700 nm, and ultraviolet light having a peak wavelength of 400 nm or less is more preferable.

Examples of the light source used for light irradiation include commonly used light sources, for example, lamps such as a tungsten lamp, a halogen lamp, a xenon lamp, a xenon flash lamp, a mercury lamp, a mercury xenon lamp, or a carbon arc lamp, various lasers [such as a semiconductor laser, a helium neon laser, an argon ion laser, a helium cadmium laser, and a yttrium aluminum garnet (YAG) laser], a light emitting diode, and a cathode ray tube.

As means for obtaining linearly polarized light, a method of using a polarizing plate (for example, an iodine polarizing plate, a dichroic substance polarizing plate, or a wire grid polarizing plate), a method of using a prism-based element (for example, a Glan-Thompson prism) or a reflective type polarizer for which a Brewster's angle is used, or a method of using light emitted from a laser light source having polarized light can be employed. Further, only light having a required wavelength may be selectively applied using a filter, a wavelength conversion element, or the like.

In a case where light to be applied is linearly polarized light, a method of applying light vertically or obliquely to the upper surface of the alignment film or the surface of the alignment film from the rear surface is employed. The incidence angle of light varies depending on the photo-alignment material, but is preferably in a range of 0° to 90° (vertical) and more preferably in a range of 40° to 90°.

In a case where light to be applied is non-polarized light, the alignment film is irradiated with non-polarized light obliquely. The incidence angle is preferably in a range of 10° to 80°, more preferably in a range of 20° to 60°, and particularly preferably in a range of 30° to 50°.

The irradiation time is preferably in a range of 1 minute to 60 minutes and more preferably in a range of 1 minute to 10 minutes.

In a case where patterning is required, a method of performing irradiation with light using a photomask as many times as necessary for pattern preparation or a method of writing a pattern by laser light scanning can be employed.

<Aligning Step>

The aligning step is a step of aligning the dichroic substance contained in the coating film. In this manner, the light absorption anisotropic film according to the embodiment of the present invention can be obtained. In the aligning step, the dichroic substance is considered to be aligned along the liquid crystal compound aligned by the alignment film.

The aligning step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the dichroic substance contained in the liquid crystal composition may be aligned by performing the above-described coating film forming step or drying treatment. For example, in an embodiment in which the liquid crystal composition is prepared as a coating solution containing a solvent, the light absorption anisotropic film according to the embodiment of the present invention may be obtained by drying the coating film and removing the solvent from the coating film so that the dichroic substance contained in the coating film is aligned.

It is preferable that the aligning step includes a heat treatment. In this manner, the dichroic substance contained in the coating film is more aligned, and the alignment degree of the light absorption anisotropic film to be obtained is further increased.

From the viewpoint of the manufacturing suitability, the heating temperature is preferably in a range of 10° C. to 250° C. and more preferably 25° C. to 190° C. Further, the heating time is preferably in a range of 1 to 300 seconds and more preferably in a range of 1 to 60 seconds.

The aligning step may include a cooling treatment performed after the heat treatment. The cooling treatment is a treatment of cooling the coating film after being heated to room temperature (20° C. to 25° C.). In this manner, the alignment of the dichroic substance contained in the coating film is further fixed, and the alignment degree of the light absorption anisotropic film to be obtained is further increased. The cooling means is not particularly limited and can be performed according to a known method.

The light absorption anisotropic film according to the embodiment of the present invention can be obtained by performing the above-described steps.

[Other Steps]

The present production method may include a step of curing the light absorption anisotropic film after the aligning step (hereinafter, also referred to as “curing step”).

The curing step is performed by, for example, heating the film and/or irradiating (exposing) the film with light. Between these, it is preferable that the curing step is performed by irradiating the film with light.

Various light sources such as infrared rays, visible light, and ultraviolet rays can be used as the light source for curing, but ultraviolet rays are preferable. In addition, ultraviolet rays may be applied while the film is heated during curing, or ultraviolet rays may be applied through a filter that transmits only a specific wavelength.

Further, the exposure may be performed under a nitrogen atmosphere. In a case where the curing of the light absorption anisotropic film proceeds by radical polymerization, since the inhibition of polymerization by oxygen is reduced, it is preferable that exposure is performed in a nitrogen atmosphere.

[Optical Film]

An optical film according to the embodiment of the present invention includes a transparent film base material and the above-described light absorption anisotropic film disposed on the transparent film base material.

Further, the optical film according to the embodiment of the present invention may include an alignment film between the transparent film base material and the light absorption anisotropic film.

Further, the optical film according to the embodiment of the present invention may further include a polarizer having an absorption axis in a plane. It is preferable that the polarizer is disposed on a side of the light absorption anisotropic film opposite to the transparent film base material. The polarizer may be disposed in contact with the surface of the optically anisotropic film or may be disposed on the surface of the optically anisotropic film via another layer (for example, a known adhesive layer or a known pressure sensitive adhesive layer). In a case where the optical film according to the embodiment of the present invention includes the polarizer, it is preferable that the optical film according to the embodiment of the present invention is a viewing angle control film used to control a viewing angle.

Hereinafter, each member constituting the optical film according to the embodiment of the present invention will be described.

[Transparent Film Base Material]

As the transparent film base material, a known transparent resin film such as a transparent resin plate, a transparent resin sheet, or the like can be used without particular limitation. Examples of the transparent resin film include a cellulose acylate film (such as a cellulose triacetate film (refractive index of 1.48), a cellulose diacetate film, a cellulose acetate butyrate film, or a cellulose acetate propionate film), a polyethylene terephthalate film, a polyether sulfone film, a polyacrylic resin film, a polyurethane-based resin film, a polyester film, a polycarbonate film, a polysulfone film, a polyether film, a polymethylpentene film, a polyether ketone film, and a (meth)acrylonitrile film.

Among these, a cellulose acylate film which is highly transparent, has a small optical birefringence, is easily produced, and is typically used as a protective film of a polarizing plate is preferable, and a cellulose triacetate film is particularly preferable.

The thickness of the transparent film base material is typically in a range of 20 μm to 100 μm.

In the present invention, it is particularly preferable that the transparent film base material is a cellulose ester-based film having a film thickness 20 to 70

[Light Absorption Anisotropic Film]

Since the light absorption anisotropic film (light absorption anisotropic layer) according to the embodiment of the present invention is as described above, the description thereof will not be repeated.

[Alignment Film]

Since the alignment film (alignment layer) is as described above, the description thereof will not be repeated.

[Barrier Layer]

It is preferable that the optical film according to the embodiment of the present invention includes a barrier layer together with the transparent film base material and the light absorption anisotropic layer.

Here, the barrier layer is also referred to as a gas-shielding layer (oxygen-shielding layer) and has a function of protecting the polarizer of the present invention from gas such as oxygen in the atmosphere, the moisture, or the compound contained in an adjacent layer.

The barrier layer can refer to, for example, the description in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, and paragraphs [0021] to [0031] of JP2005-169994A.

[Tint Adjusting Layer]

It is preferable that the optical film according to the embodiment of the present invention includes a tint adjusting layer containing at least one coloring agent compound. It is preferable that the coloring agent compound contained in the tint adjusting layer is in a non-aligned state.

In a case where the amount of the coloring agent in the light absorption anisotropic layer is adjusted, a change in tint as viewed in an oblique direction with respect to the transmittance central axis is increased, but the change in tint in the oblique direction with respect to the change in tint of the transmittance central axis can be suppressed by adjusting the tint using the tint adjusting layer.

The tint adjusting layer may have only the function of the tint adjusting layer or may have functions integrated with functions of other layers.

The absorption peak wavelength of the coloring agent compound contained in the tint adjusting layer used in the present invention is preferably 500 nm or greater and 650 nm or less and more preferably 550 nm or greater and 600 nm or less. The tint of the optical film in the present invention can be adjusted to be more neutral by setting the absorption of the coloring agent compound to be in the above-described ranges.

Examples of the coloring agent compound contained in the tint adjusting layer include azo, methine, anthraquinone, triarylmethane, oxazine, azomethine, phthalocyanine, porphyrin, perylene, pyrrolopyrrole, and squarylium. Among these, from the viewpoints of enhancing the absorption waveform, the heat resistance, and the light resistance, azo, phthalocyanine, and anthraquinone are preferable, and anthraquinone is particularly preferable. Other examples thereof include coloring agent compounds described in “Functional Coloring Agents”, co-authored by Shin Okawara, Ken Matsuoka, Tsuneaki Hirashima, and Eijiro Kitao, Kodansha Ltd., 1992, supervised by Sumio Tokita, and “Electronics-related Materials”, CMC Publishing Co., Ltd., 1998.

Specific examples of the coloring agent compound used in the present invention are shown below, but the present invention is not limited thereto. In the following formulae, Me represents a methyl group, Et represents an ethyl group, n-Bu represents a normal butyl group, Bn represents a benzyl group, and Ph represents a phenyl group.

Anthraquinone

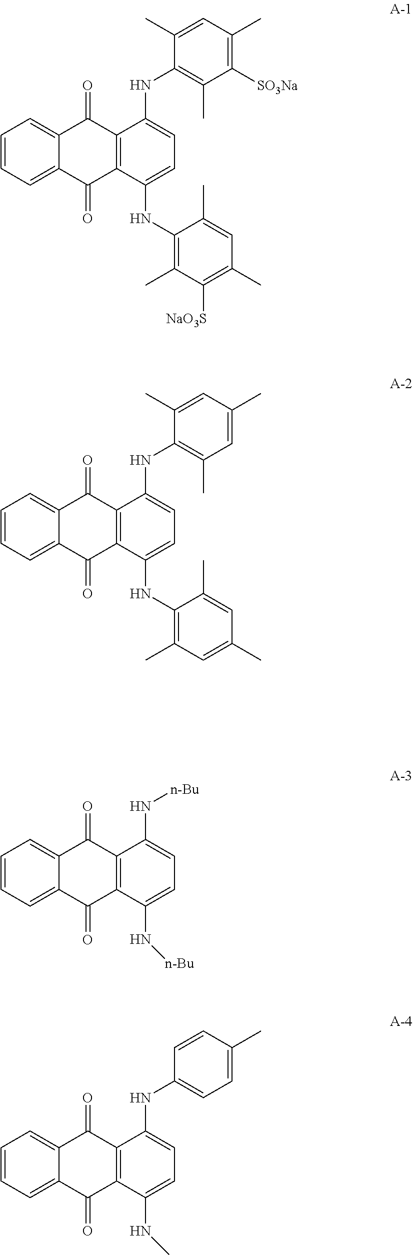

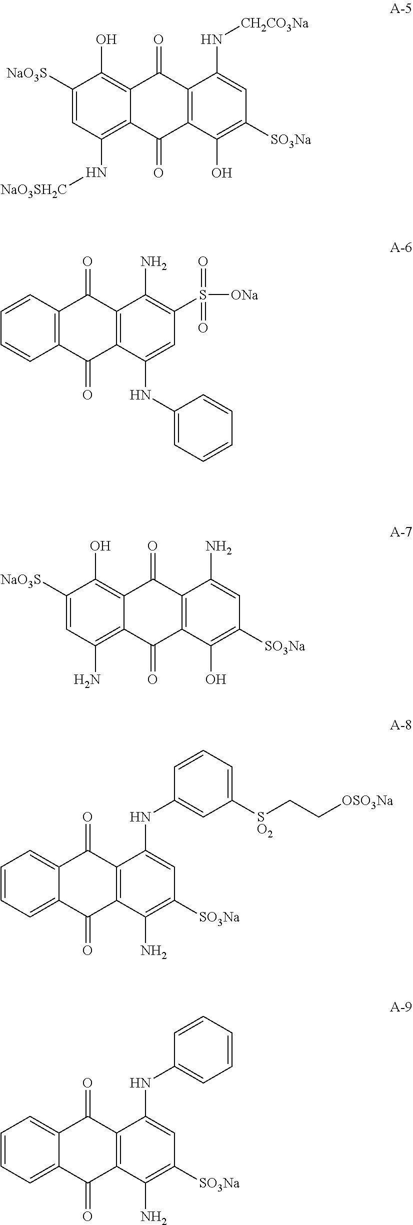

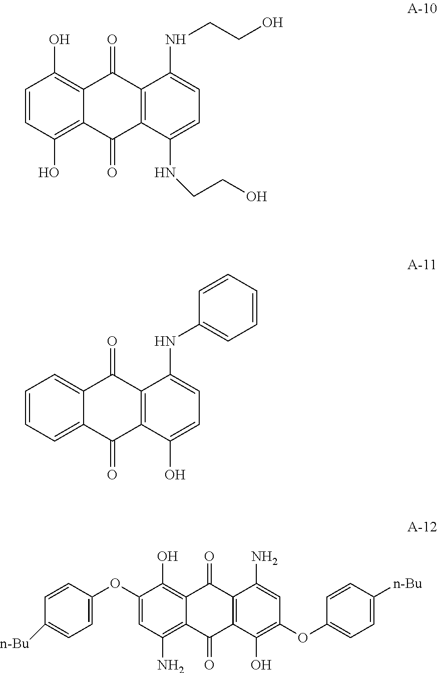

Azo

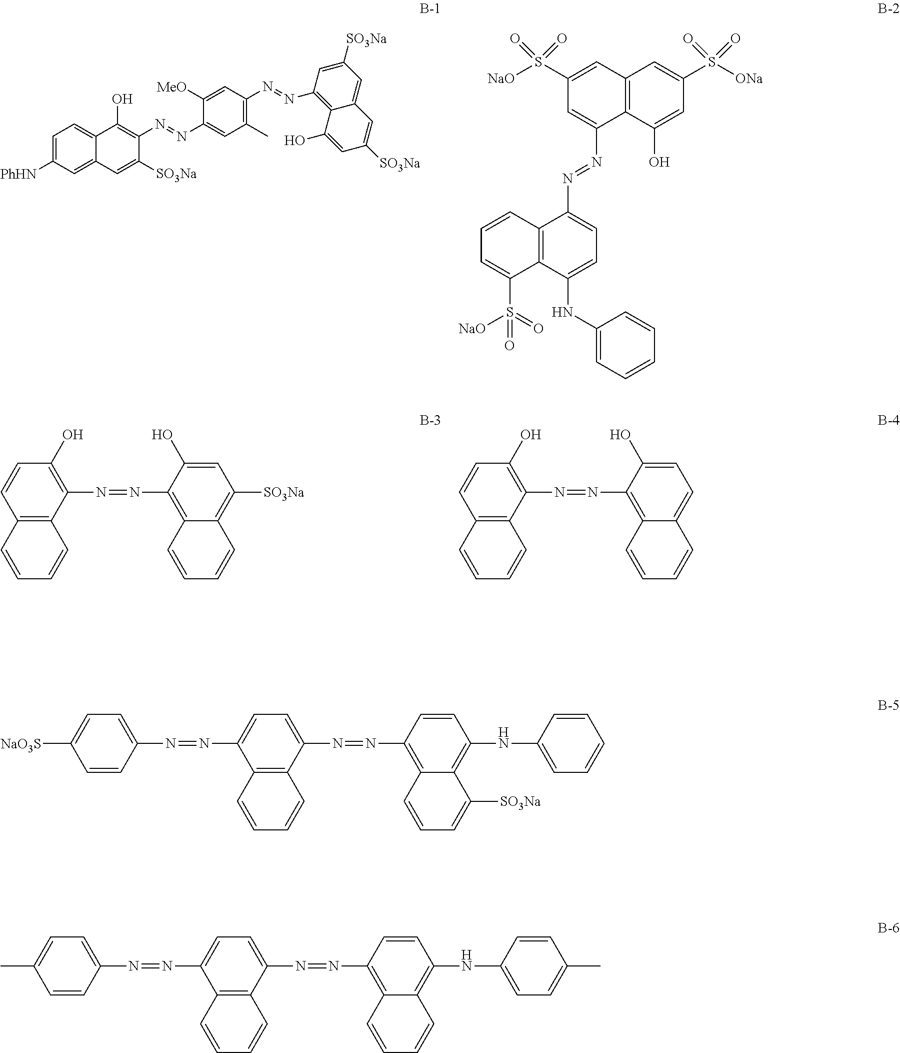

Triarylmethane

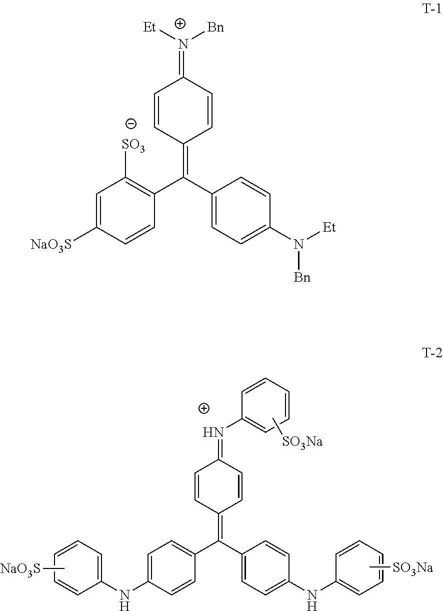

Oxazine

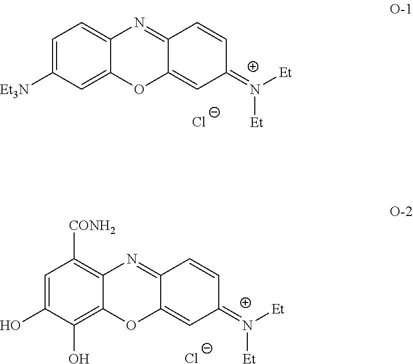

Phthalocyanine

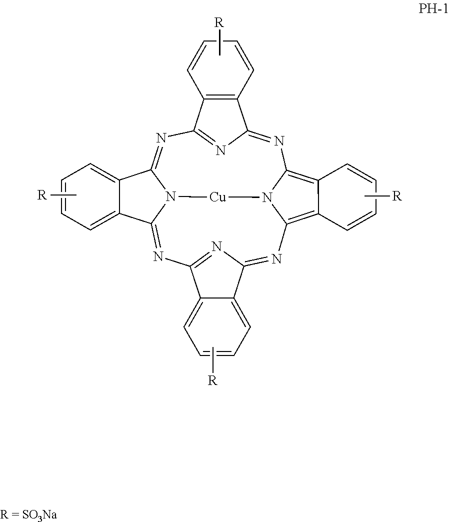

[Polarizer]

The polarizer used in the present invention is not particularly limited as long as the polarizer is a member having an absorption axis in the plane and having a function of converting light into specific linearly polarized light, and a known polarizer of the related art can be used. As the polarizer, an iodine-based polarizer, a dye-based polarizer formed of a dichroic dye, a polyene-based polarizer, or the like is used. Examples of the iodine-based polarizer and the dye-based polarizer include a coating type polarizer and a stretching type polarizer, and both polarizers can be applied.

A polarizer in which a dichroic organic coloring agent is aligned by using alignment of the liquid crystal compound is preferable as the coating type polarizer, and a polarizer prepared by adsorbing iodine or a dichroic dye on polyvinyl alcohol and stretching the polyvinyl alcohol is preferable as the stretching type polarizer.

Examples thereof include a light absorption anisotropic layer containing a dichroic coloring agent compound that is horizontally aligned (direction intersecting the thickness direction of the light absorption anisotropic film) without containing the liquid crystal compound described in JP2010-152351A and a light absorption anisotropic layer containing the liquid crystal compound described in WO2017/154907A and a horizontally aligned dichroic coloring agent compound.

Further, examples of the method of obtaining a polarizer by stretching and dyeing a laminated film in which a polyvinyl alcohol layer is formed on a base material include methods described in JP5048120B, JP5143918B, JP4691205B, JP4751481B, and JP4751486B, and known techniques related to these polarizers can also be preferably used.

Here, the horizontal alignment denotes that a molecular axis of the liquid crystal compound or the dichroic coloring agent compound (for example, a major axis corresponds to the molecular axis in a case of a rod-like liquid crystal compound) is parallel to the main surface of the polarizer, but the axis is not required to be strictly parallel to the surface, and the tilt angle between an average molecular axis of the liquid crystal compound for the dichroic coloring agent compound in the polarizer and the main surface of the polarizer is less than ±10°. Further, the tilt angle can be measured using AxoScan OPMF-1 (manufactured by Opto Science, Inc.).

Specifically, an extinction coefficient ko [λ] (in-plane direction) and an extinction coefficient ke [λ] (thickness direction) are calculated using AxoScan OPMF-1 (manufactured by Opto science, Inc.) by measuring the Mueller matrix of the polarizer at a wavelength λ and at room temperature while the polar angle is changed from −50° to 50° by 10°, removing the influence of the surface reflection, and fitting the result to the following theoretical formula in consideration of the Snell's formula and Fresnel's equations. Unless otherwise specified, the wavelength λ is 550 nm.

k=−log (T)×λ/(4πd)

Here, T represents the transmittance, and d represents the thickness of the polarizer.

By calculating the absorbance and the dichroic ratio in the in-plane direction and the thickness direction based on the calculated ko [λ] and ke [λ], it can be confirmed whether the liquid crystal compound and the dichroic substance are horizontally aligned.

[Applications]

The optical film according to the embodiment of the present invention is not limited thereto, and is suitably used for preventing peeping into a display device and controlling a viewing angle range.

[Display Device]

A display device (image display device) according to the embodiment of the present invention includes the optical film including the polarizer described above and a display element.

It is preferable that the display element is disposed on the polarizer side of the optical film (that is, a side of the optical film opposite to the transparent film base material). The polarizer and the liquid crystal cell may be laminated via a known adhesive layer or a known pressure sensitive adhesive layer.

The display element used in the display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable. That is, as the display device according to the embodiment of the present invention, a liquid crystal display device obtained by using a liquid crystal cell as a display element or an organic EL display device obtained by using an organic EL display panel as a display element is preferable.

Some image display devices are thin and can be molded into a curved surface. Since a light absorption anisotropic film used in the present invention is thin and easily bent, the light absorption anisotropic film can be suitably applied to an image display device having a curved display surface.

Further, some image display devices have a pixel density of greater than 250 ppi and are capable of high-definition display. The light absorption anisotropic film used in the present invention can be suitably applied to such a high-definition image display device without causing moire.

[Liquid Crystal Display Device]

As the liquid crystal display device which is an example of the display device according to the embodiment of the present invention, an aspect in which a display device includes the above-described optical film including the polarizer and a liquid crystal cell is preferable.

Examples of the specific configuration thereof include a configuration in which the optical film according to the embodiment of the present invention is disposed on a front-side polarizing plate or a rear-side polarizing plate. In these configurations, the viewing angle at which the vertical direction or the horizontal direction is light-shielded can be controlled.

In addition, the optical film according to the embodiment of the present invention may be disposed on both the front-side polarizing plate and the rear-side polarizing plate. With such a configuration, it is possible to control the viewing angle in which the omniazimuth is light-shielded and light is transmitted only in the front direction.

Further, a plurality of the optical films according to the embodiment of the present invention may be laminated via a retardation layer. By controlling the retardation value and the optical axis direction, the transmission performance and the light shielding performance can be controlled. For example, the omniazimuth is light-shielded by arranging the polarizer, the optical laminate, the λ/2 wave plate (the axis angle is an angle deviated by 45° from the alignment direction of the polarizer), and the optical film so that the viewing angle control in which light is transmitted only in the front direction can be made. As the retardation layer, a positive A-plate, a negative A-plate, a positive C-plate, a negative C-plate, a B plate, an O plate, or the like can be used. From the viewpoint of reducing the thickness of the viewing angle control system, it is preferable that the thickness of the retardation layer is small as long as the optical characteristics, the mechanical properties, and the manufacturing suitability are not impaired, and specifically, the thickness thereof is preferably in a range of 1 to 150 μm, more preferably in a range of 1 to 70 μm, and still more preferably in a range of 1 to 30 μm.

Hereinafter, the liquid crystal cell constituting the liquid crystal display device will be described in detail.

<Liquid Crystal Cell>

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in a TN mode, rod-like liquid crystal molecules are substantially horizontally aligned at the time of no voltage application and further twisted aligned at 60° to 120°. The liquid crystal cell in a TN mode is most frequently used as a color TFT liquid crystal display device and is described in a plurality of documents.

In the liquid crystal cell in a VA mode, rod-like liquid crystal molecules are substantially vertically aligned at the time of no voltage application. The concept of the liquid crystal cell in a VA mode includes (1) a liquid crystal cell in a VA mode in a narrow sense where rod-like liquid crystal molecules are aligned substantially vertically at the time of no voltage application and substantially horizontally at the time of voltage application (described in JP1990-176625A (JP-H02-176625A)), (2) a liquid crystal cell (in an MVA mode) (SID97, described in Digest of tech. Papers (proceedings) 28 (1997) 845) in which the VA mode is formed to have multi-domain in order to expand the viewing angle, (3) a liquid crystal cell in a mode (n-ASM mode) in which rod-like liquid crystal molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). Further, the liquid crystal cell may be of any of a patterned vertical alignment (PVA) type, a photo-alignment (optical alignment) type, or a polymer-sustained alignment (PSA) type. The details of these modes are described in JP2006-215326A and JP2008-538819A.

In the liquid crystal cell in an IPS mode, liquid crystal compounds are aligned substantially parallel to the substrate, and the liquid crystal molecules respond planarly through application of an electric field parallel to the substrate surface. That is, the liquid crystal compounds are aligned in the plane in a state where no electric field is applied. In the IPS mode, black display is carried out in a state where no electric field is applied, and absorption axes of a pair of upper and lower polarizing plates are orthogonal to each other. A method of reducing leakage light during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

[Organic EL Display Device]

As an organic EL display device which is an example of the display device according to the embodiment of the present invention, an aspect of a display device that includes the above-described optical film including the polarizer, a λ/4 plate, and an organic EL display panel in this order from the viewing side is suitably exemplified.

Further, similarly to the liquid crystal display device described above, a plurality of the optical films according to the embodiment of the present invention may be laminated via the retardation layer and disposed on the organic EL display panel. By controlling the retardation value and the optical axis direction, the transmission performance and the light shielding performance can be controlled.

Further, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to examples. The materials, the used amounts, the ratios, the treatment contents, the treatment procedures, and the like described in the following examples can be appropriately changed without departing from the spirit of the present invention. Therefore, the scope of the present invention should not be limitatively interpreted by the following examples.

### Example 1

An optical film A of Example 1 was produced as follows.

<Formation of Alignment Film>

A surface of a cellulose acylate film (TAC base material having a thickness of 40 μm; TG40, FUJIFILM Corporation) was saponified with an alkaline solution and coated with a composition 1 for forming an alignment film using a wire bar. The support on which the coating film was formed was dried with hot air at 60° C. for 60 seconds and further dried with hot air at 100° C. for 120 seconds to form an alignment film 1, thereby obtaining a TAC film 1 with an alignment film. The film thickness of the alignment film was 1

(Composition 1 for forming alignment film)

| | | |
|---|---|---|
| Modified polyvinyl alcohol PVA-1: | 3.80 | parts by mass |
| IRGACURE 2959: | 0.20 | parts by mass |
| Water: | 70 | parts by mass |
| Methanol: | 30 | parts by mass |

Modified polyvinyl alcohol PVA-1

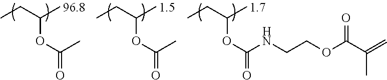

[Preparation of Light Absorption Anisotropic Film 1]

The obtained alignment film 1 was continuously coated with the following liquid crystal composition 1 using a wire bar, heated at 120° C. for 60 seconds, and cooled to room temperature (23° C.).

Next, the coating layer P1 was heated at 80° C. for 60 seconds and cooled to room temperature again.

Thereafter, the film was irradiated with light of a light emitting diode (LED) (central wavelength of 365 nm) under an irradiation condition of an illuminance of 200 mW/cm² for 2 seconds, thereby preparing a light absorption anisotropic film 1 on the alignment film 1. The film thickness of the light absorption anisotropic film 1 was 3.5 μm.

In this manner, an optical film A in which the light absorption anisotropic film 1 was laminated on the alignment film 1 of the TAC film 1 with an alignment film was obtained.

Composition of liquid crystal composition 1

| | | |
|---|---|---|
| Polymer liquid crystal compound L1 shown below: | 6.704 | parts by mass |
| Low-molecular-weight liquid crystal compound L2 shown below: | 4.052 | parts by mass |
| Dichroic substance Y1 shown below: | 0.650 | parts by mass |
| Dichroic substance M1 shown below: | 0.148 | parts by mass |
| Dichroic substance C1 shown below: | 0.805 | parts by mass |
| Dichroic substance C2 shown below: | 0.130 | parts by mass |
| Interface improver B1 shown below: | 0.004 | parts by mass |
| Vertical alignment agent B2 shown below: | 0.156 | parts by mass |
| Vertical alignment agent B3 shown below: | 0.156 | parts by mass |
| Polymerization initiator (IRGACURE OXE-02, manufactured by BASF SE): | 0.195 | parts by mass |
| Cyclopentanone (solvent): | 87.000 | parts by mass |

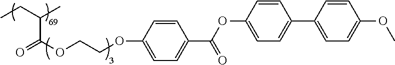

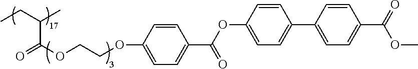

L1 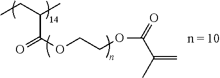 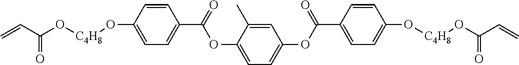
L2 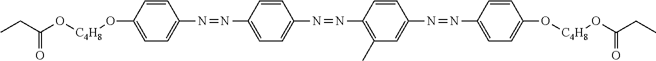
Y1 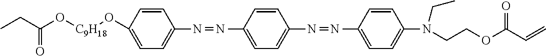
M1 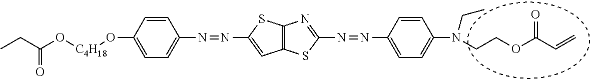
C1 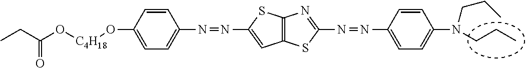
C2 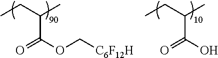
B1 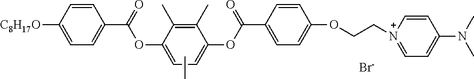
B2 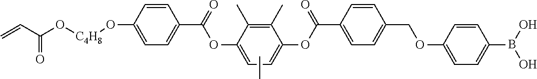
B3

### Examples 2 to 12 and Comparative Examples 1 to 4

Each optical film of Examples 2 to 12 and Comparative Examples 1-4 was prepared by the same method as that for the optical film A of Example 1 except that the alignment film and the liquid crystal composition were changed to the alignment film and the liquid crystal composition having the compositions listed in Table 1.

An outline of components contained in the liquid crystal composition used for preparing each optical film of the examples and the comparative examples is shown below.

<Formation of Alignment Film 2>

A cellulose acylate film (TAC base material having a thickness of 40 μm; TG40, FUJIFILM Corporation) was continuously coated with the following composition 2 for forming an alignment film using a wire bar. The support on which the coating film was formed was dried with hot air at 140° C. for 120 seconds to form an alignment film 2, thereby obtaining a TAC film 2 with an alignment film. The film thickness of the alignment film 2 was 0.5 μm.

(Composition 2 for forming alignment film)

| | | |
|---|---|---|
| Polymer PA2 shown below: | 100.00 | parts by mass |
| Acid generator PAG-1 shown below: | 8.25 | parts by mass |
| Stabilizer DIPEA shown below: | 0.6 | parts by mass |
| Methyl ethyl ketone: | 250.36 | parts by mass |
| Butyl acetate: | 1001.42 | parts by mass |

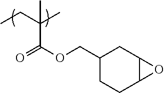

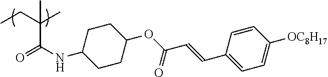

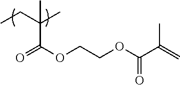

PA2 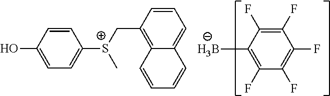
PAG-1 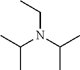
DIPEA
Polymer liquid crystal compound (structure shown below) 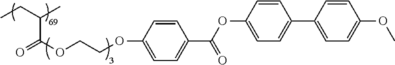 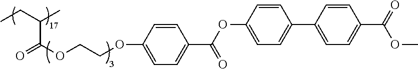
L1 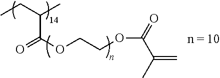
Low-molecular-weight liquid crystal compound (structure shown below) 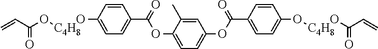
L2 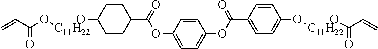
L3 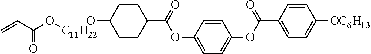
L4
Dichroic substance Y (structure shown below) 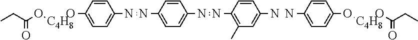
Y1 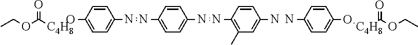
Y2
Dichroic substance M (structure shown below) 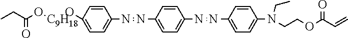
M1 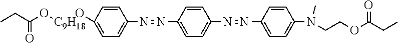
M2
Dichroic substance C-1 and dichroic substance C-2 (structure shown below) 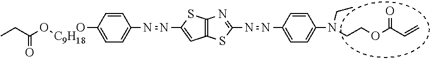
C1 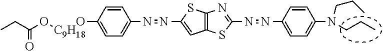
C2 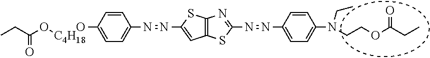
C3 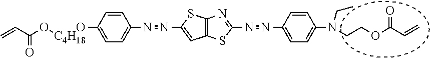
C4 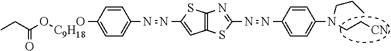
C5 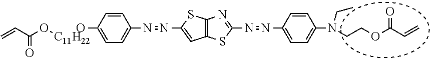
C6 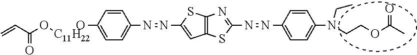
C7 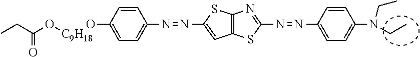
C8 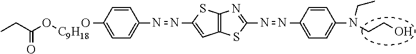
C9 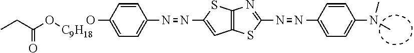
C10 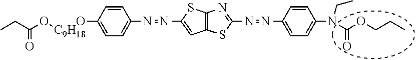
C11 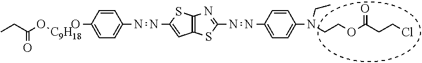
C12

Here, in the chemical formulae of the dichroic substances corresponding to the dichroic substance C-1 and the dichroic substance C-2 described above, the groups in the dotted frame denote a group corresponding to R^{b12} in Formula (C-1) and a group corresponding to R^{b22} in Formula (C-2).

Interface improver B1 (structure shown above)

Vertical alignment agent B2 (structure shown above)

Vertical alignment agent B3 (structure shown below)

Interface improver B4 (structure shown below)

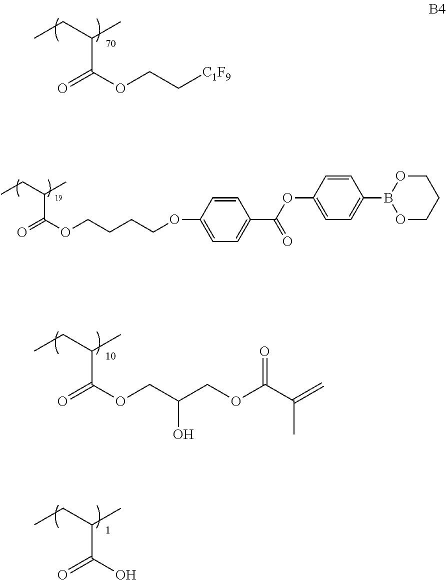

Polymerization initiator (IRGACURE OXE-02, manufactured by BASF SE)

Cyclopentanone (solvent)

[Evaluation Test]

The following evaluations were performed using the optical films of the examples and the comparative examples obtained as described above.

Further, as a result of evaluation performed on the light absorption anisotropic films included in the optical films of each example by the method of evaluating vertical alignment described above, all the light absorption anisotropic films included in the optical films of each example were formed such that the polymer liquid crystal compound and the dichroic substance were vertically aligned.

[Alignment Degree]

The Mueller matrix of the vertically polarizing layer at a wavelength λ was measured with AxoScan OPMF-1 (manufactured by Opto science, Inc.) using each optical film of the examples and the comparative examples while the polar angle was changed from −50° to 50° by 10°. After the influence of surface reflection was removed, ko [λ] and ke [λ] were calculated by fitting the result to the following theoretical formula in consideration of the Snell's formula and Fresnel's equations.

k=−log P(T)×λ/(4πd)

The absorbance and the dichroic ratio in the in-plane direction and the thickness direction were calculated based on the obtained ko [λ] and ke [λ], and the vertical alignment degree was finally acquired.

Based on the obtained vertical alignment degree, the alignment degree was evaluated according to the following evaluation standards. The results are listed in Table 1.

A: The vertical alignment degree was 0.965 or greater.

B: The vertical alignment degree was 0.935 or greater and less than 0.965.

C: The vertical alignment degree was 0.90 or greater and less than 0.935.

D: The vertical alignment degree was less than 0.90.

[Defects]

Each optical film of the examples and the comparative examples was prepared in the same manner as in the preparation of the optical film A described above except that each liquid crystal composition used in the examples and the comparative examples was heated at 45° C. for 15 minutes and allowed to stand at room temperature for 1 hour.

One linear polarizer was inserted on each of a light source side and an objective lens side of an optical microscope (product name, “ECLIPSE E600 POL”, manufactured by Nikon Corporation), and the respective linear polarizers were disposed with a shift of 90°. The above-described optical film was set on a sample table, 5 sites were randomly selected from the set optical film, and observation was performed using a microscope with a 5× objective lens. The average value of the number of defects at the measured five sites was calculated, and the defects were evaluated according to the following evaluation standards. The results are listed in Table 1.
A: The average value of the number of defects was less than 2.
B: The average value of the number of defects was 2 or greater and less than 5.
C: The average value of the number of defects was 5 or greater and less than 10.
D: The average value of the number of defects was 10 or greater.

In Table 1, “difference in HSP value” denotes an absolute value of the difference between the HSP value of the group corresponding to R^{b12} in Formula (C-1) and the HSP value of the group corresponding to R^{b22} in Formula (C-2).

In Table 1, “total amount of C-1 and C-2” denotes the total content of the dichroic substance C-1 and the dichroic substance C-2 with respect to the total mass of the solid content of the liquid crystal composition.

TABLE 1

| | | Liquid crystal | | Liquid crystal | | [symbol] | | [symbol] | | [symbol] | | [symbol] | | [symbol] | |
|---|---|---|---|---|---|---|---|---|---|---|---|---|---|---|---|
| | | compound | | compound | | substance Y | | substance M | | substance C-1 | | substance C-2 | | substance C- [symbol] | |
| | Alignment | | Parts | | Parts | | Parts | | Parts | | Parts | | Parts | | Parts |
| | degree | Type | by mass | Type | by mass | Type | by mass | Type | by mass | Type | by mass | Type | by mass | Type | by mass |
| Example 1 | 1 | L1 | 6.704 | L2 | 4.052 | Y1 | 0.6 [symbol] 0 | M1 | 0.148 | C1 | 0.805 | C2 | 0.130 | | |
| Example 2 | 1 | L1 | 6.428 | L2 | 3.886 | Y2 | 0. [symbol] 53 | M2 | 0.1 [symbol] | C1 | 0.893 | C3 | 0.285 | | |
| Example 3 | 2 | L1 | 4.788 | L2 | 3.173 | Y2 | 0. [symbol] | M2 | 0.154 | C1 | 0.102 | C4 | 0.992 | | |
| Example 4 | 1 | L1 | 4.824 | L2 | 3.184 | Y2 | 0. [symbol] 15 | M2 | 0.166 | C1 | 0.618 | C5 | 0.487 | | |
| Example 5 | 1 | L1 | 6.794 | L2 | 4.100 | Y1 | 0. [symbol] 06 | M2 | 0.2 [symbol] 9 | C1 | 0.580 | C3 | 0. [symbol] 58 | | |
| Example 6 | 2 | L1 | 6.25 [symbol] | L2 | 3.864 | Y1 | 0. [symbol] 5 [symbol] | M1 | 0.1 [symbol] 1 | C6 | 0.978 | C7 | 0.095 | | |
| Example 7 | 1 | L1 | 5.436 | L2 | 3.311 | Y2 | 0.561 | M1 | 0.13 [symbol] | C3 | 0.841 | C8 | 0.09 [symbol] | | |
| Example 8 | 1 | L1 | 4.918 | L2 | 3.245 | Y1 | 0.627 | M1 | 0.169 | C1 | 0.789 | C3 | 0.338 | | |
| Example 9 | 2 | L3 | 7.805 | L4 | 2.602 | Y2 | 0.637 | M2 | 0.16 [symbol] | C1 | 0.663 | C3 | 6.637 | | |
| Example 10 | 1 | L1 | 4.89 [symbol] | L2 | 3.201 | Y1 | 0. [symbol] 44 | M1 | 0.191 | C1 | 0.624 | C9 | 0.526 | | |
| Example 11 | 1 | L1 | 5.00 [symbol] | L2 | 3.434 | Y1 | 0.529 | M2 | 0.105 | C1 | 0.807 | C11 | 0.20 [symbol] | | |
| Example 12 | 1 | L1 | 5.083 | L2 | 3.302 | Y2 | 0.568 | M2 | 0.128 | C1 | 0.849 | C12 | 0.212 | | |
| Comparative | 1 | L1 | 5.159 | L2 | 3. [symbol] 70 | Y2 | 0.578 | M2 | 0.138 | C1 | 1.038 | | | | |
| Example 1 | | | | | | | | | | | | | | | |
| Comparative | 1 | L1 | 4. [symbol] | L2 | 3.236 | Y1 | 0.5 [symbol] 4 | M1 | 0.1 [symbol] 6 | | | C10 | 0. [symbol] 90 | C8 | 0.590 |
| Example 2 | | | | | | | | | | | | | | | |
| Comparative | 1 | L1 | 7.357 | L2 | 4.0 [symbol] 6 | Y2 | 0.486 | M2 | 0.090 | C1 | 0.281 | C3 | 0.281 | | |
| Example 3 | | | | | | | | | | | | | | | |
| Comparative | 1 | L1 | 7.364 | L4 | 4.060 | Y2 | 0.487 | M2 | 0.090 | C1 | 0.282 | C3 | 0.269 | | |
| Example 4 | | | | | | | | | | | | | | | |

| | Total | | Inter [symbol] | | Vertical | | Vertical | | Polymerization | | | |
|---|---|---|---|---|---|---|---|---|---|---|---|---|
| | amount | Difference | [symbol] | | alignment agent | | alignment agent | | initiator | [symbol] | | |
| | of C-1 | in [symbol] | | Parts | | Parts | | Parts | Parts | Parts | | Alignment |
| | and C-2 | value | Type | by mass | Type | by mass | Type | by mass | by mass | by mass | [symbol] | degree |
| Example 1 | 7.2 | 3.3 | B1 | 0.004 | B2 | 0.136 | B3 | 0.1 [symbol] 6 | 0.195 | 87.00 [symbol] | C | B |
| Example 2 | [symbol] .2 | 0.3 | B4 | 0.004 | B2 | 0.151 | B3 | 0.15 [symbol] | 0.189 | 8 [symbol] .200 | A | A |
| Example 3 | 10.7 | 0.0 | B4 | 0.004 | B2 | 0.122 | B3 | 0.122 | 0.153 | 89.8 [symbol] 0 | A | B |
| Example 4 | 10.7 | 3.8 | B1 | 0.004 | B2 | 0.124 | B3 | 0.124 | 0.154 | 89.700 | C | A |
| Example 5 | 6.4 | 0.3 | B1 | 0.001 | B2 | 0.135 | B3 | 0.1 [symbol] 5 | 0.193 | 86.900 | A | B |
| Example 6 | 8. [symbol] | 0.2 | B1 | 0.004 | B2 | 0.150 | B3 | 0.150 | 0.18 [symbol] | 8 [symbol] .500 | B | B |
| Example 7 | 8. [symbol] | 2.8 | B1 | 0.004 | B2 | 0.13 [symbol] | B3 | 0.1 [symbol] | 0.163 | 89.200 | B | C |
| Example 8 | 10.7 | 0.3 | B1 | 0.004 | B2 | 0.126 | B3 | 0.126 | 0.157 | 89.500 | A | A |
| Example 9 | 10.0 | 0.3 | B4 | 0.005 | B2 | 0.143 | B3 | 0.143 | 0.195 | 87.000 | A | C |
| Example 10 | 11.0 | 7.5 | B1 | 0.004 | B2 | 0.126 | B3 | 0.126 | 0.158 | 89.300 | C | B |
| Example 11 | 9.7 | 1.1 | B1 | 0.004 | B2 | 0.125 | B3 | 0.125 | 0.157 | 89.500 | B | B |
| Example 12 | 10.1 | 1. [symbol] | B1 | 0.004 | B2 | 0.127 | B3 | 0.127 | 0.159 | 89.440 | B | B |
| Comparative | 9.9 | — | B1 | 0.004 | B2 | 0.127 | B3 | 0.127 | 0.15 [symbol] | 89.500 | D | A |
| Example 1 | | | | | | | | | | | | |
| Comparative | 11.2 | — | B1 | 0.004 | B2 | 0.124 | B3 | 0.124 | 0.155 | 89.500 | D | C |
| Example 2 | | | | | | | | | | | | |
| Comparative | 4.3 | 0.3 | B1 | 0.00 [symbol] | B2 | 0.128 | B3 | 0.128 | 0.192 | 87.000 | A | D |
| Example 3 | | | | | | | | | | | | |
| Comparative | 4.2 | 0.3 | B1 | 0.00 [symbol] | B2 | 0.128 | B3 | 0.128 | 0.192 | 87.000 | A | D |
| Example 4 | | | | | | | | | | | | |

[symbol]

indicates data missing or illegible when filed

As listed in Table 1, a light absorption anisotropic film formed of a liquid crystal composition containing a liquid crystal compound, a dichroic substance C-1, and a dichroic substance C-2, in which the total content of the dichroic substance C-1 and the dichroic substance C-2 with respect to the total mass of the solid content of the liquid crystal composition was 4.5% by mass or greater and the liquid crystal compound was vertically aligned had less defects and exhibited a high alignment degree (Examples 1 to 12).

Based on the comparison between Examples 2 and 5, it was found that in a case where the total content of the dichroic substance C-1 and the dichroic substance C-2 was 6.5 mass or greater with respect to the total mass of the solid content of the liquid crystal composition (Example 2), the alignment degree was more excellent.

Based on the comparison of Examples 1, 2, and 7, it was found that as the group corresponding to R^{b22} in Formula (C-2), the dichroic substance C-2 which is a monovalent aliphatic hydrocarbon group having 1 to 20 carbon atoms which may have a monovalent substituent or a monovalent group in which —CH2-constituting a monovalent aliphatic hydrocarbon group having 1 to 20 carbon atoms which may have a monovalent substituent is substituted with a divalent substituent is used (Example 2), the alignment degree and the resistance to defects were more excellent.

Based on the comparison of Example 1, Example 2, Example 4, and Example 10, it is found that in a case where the difference in HSP value was 3.0 or less (Example 2), at least one of the alignment degree or the resistance to defects was more excellent.

Based on the comparison between Examples 2 and 6, it was found that in a case where the mass ratio of the content of the dichroic substance C-1 to the amount of the dichroic substance C-2 was in a range of 0.100 to 10.0 (Example 2), the alignment degree and the resistance to defects were more excellent.

Based on the comparison between Example 2 and Example 9, it was found that in a case where the liquid crystal compound contained a polymer liquid crystal compound (Example 2), the alignment degree was more excellent.

On the contrary, as listed in Table 1, it was found that in a case where a liquid crystal composition containing only one of the dichroic substance C-1 or the dichroic substance C-2 was used (Comparative Examples 1 and 2) and in a case where the total content of the dichroic substance C-1 and the dichroic substance C-2 with respect to the total mass of the solid content of the liquid crystal composition was less than 4.5% by mass (Comparative Examples 3 and 4), at least one of the alignment degree or the resistance to defects was degraded (comparative examples).

### Example 13

<Formation of Tint Adjusting Layer G1>

The light absorption anisotropic film 1 obtained in Example 1 was continuously coated with the following composition G1 for forming a tint adjusting layer using a wire bar, thereby forming a coating film.

Next, the support on which the coating film was formed was dried with hot air at 60° C. for 60 seconds and further dried with hot air at 100° C. for 120 seconds to form a tint adjusting layer C1, thereby obtaining an optical film 1. The film thickness of the tint adjusting layer was 0.5 μm.

(Composition G1 for forming tint adjusting layer)

| | | |
|---|---|---|
| Modified polyvinyl alcohol PVA-1 shown above: | 3.80 | parts by mass |
| IRGACURE 2959: | 0.20 | parts by mass |
| Coloring agent compound G-1: | 0.08 | parts by mass |
| Water: | 70 | parts by mass |
| Methanol: | 30 | parts by mass |

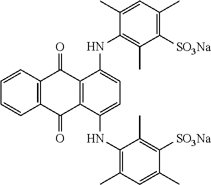

G-1

<Preparation of Optical Laminate A1>

A polarizing plate 1 in which the thickness of the polarizer was 8 μm and one surface of the polarizer was exposed was prepared by the same method as that for a polarizing plate 02 with a one-surface protective film described in WO2015/166991A.

The surface of the polarizing plate 1 in which the polarizer was exposed and the surface of the tint adjusting layer of the prepared optical film 1 were subjected to a corona treatment, and both surfaces were bonded to each other with the following PVA adhesive 1, thereby preparing an optical laminate A1.

(Preparation of PVA Adhesive 1)

20 parts of methylol melamine with respect to 100 parts of a polyvinyl alcohol-based resin containing an acetoacetyl group (average degree of polymerization: 1200, degree of saponification: 98.5% by mole, degree of acetoacetylation: 5% by mole) was dissolved in pure water under a temperature condition of 30° C. to prepare an aqueous solution in which the concentration of solid contents was adjusted to 3.7%.

<Preparation of Image Display Device A1>

A Wi-Fi model iPad Air (manufactured by APPLE, Inc.) with a capacity of 16 GB, which is an IPS mode liquid crystal display device, was disassembled to take out the liquid crystal cell. The viewing-side polarizing plate was peeled off from the liquid crystal cell, the laminate A1 prepared above was bonded to the surface formed by peeling the viewing-side polarizing plate such that the polarizing plate 1 side was the liquid crystal cell side, using the following pressure sensitive adhesive sheet 1. At this time, the bonding was carried out such that the direction of the absorption axis of the polarizing plate 1 was the same as the direction of the absorption axis of the viewing-side polarizing plate bonded to the product. After the bonding, the device was assembled again, thereby preparing an image display device A1.

### (Preparation of Pressure Sensitive Adhesive Sheet 1)

An acrylate-based polymer was prepared according to the following procedures.

95 parts by weight of butyl acrylate and 5 parts by weight of acrylic acid were polymerized by a solution polymerization method in a reaction container equipped with a cooling pipe, a nitrogen introduction pipe, a thermometer, and a stirrer, thereby obtaining an acrylate-based polymer (A1) with an average molecular weight of 2000000 and a molecular weight distribution (Mw/Mn) of 3.0.

Next, the obtained acrylate-based polymer A1 (100 parts by mass), CORONATE L (75 mass % ethyl acetate solution of trimethylolpropane adduct of tolylene isocyanate, number of isocyanate groups in one molecule: 3, manufactured by Nippon Polyurethane Industry Co., Ltd.) (1.0 parts by mass), and a silane coupling agent KBM-403 (manufactured by Shin-Etsu Chemical Co., Ltd.) (0.2 parts by mass) were mixed with each other, and ethyl acetate was finally added to the mixture such that the total concentration of solid contents reached 10% by mass, thereby preparing a composition for forming a pressure sensitive adhesive. A separate film subjected to a surface treatment with a silicone-based release agent was coated with the composition using a die coater and dried in an environment of 90° C. for 1 minute, thereby obtaining an acrylate-based pressure sensitive adhesive sheet. The film thickness thereof was 25 μm, and the storage elastic modulus thereof was 0.1 MPa.

In a case where a white display was performed using the image display device prepared in Example 13, the tints in the front direction and in an oblique direction were both neutral.

What is claimed is:

1. A light absorption anisotropic film formed of a liquid crystal composition containing a liquid crystal compound, a dichroic substance represented by Formula (C-1), a dichroic substance represented by Formula (C-2),
wherein a total content of the dichroic substance represented by Formula (C-1) and the dichroic substance represented by Formula (C-2) is 4.5% by mass or greater with respect to a total mass of a solid content of the liquid crystal composition, and
the liquid crystal compound is vertically aligned, 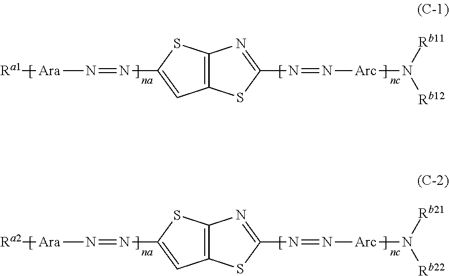
in Formula (C-1) and Formula (C-2), R^{a1} and R^{a2} each independently represent a hydrogen atom, a monovalent aliphatic hydrocarbon group having 1 to 20 carbon atoms which may have a monovalent substituent, or a monovalent group in which —CH₂— constituting a monovalent aliphatic hydrocarbon group having 1 to 20 carbon atoms which may have a monovalent substituent is substituted with a divalent substituent,
Ara and Arc each independently represent a divalent aromatic group which may have a monovalent substituent,
R^{b11}, R^{b21}, and R^{b22} each independently represent a hydrogen atom, a monovalent aliphatic hydrocarbon group having 1 to 20 carbon atoms which may have a monovalent substituent, or a monovalent group in which —CH₂— constituting a monovalent aliphatic hydrocarbon group having 1 to 20 carbon atoms which may have a monovalent substituent is substituted with a divalent substituent,
R^{b12} represents a monovalent aliphatic hydrocarbon group having 1 to 20 carbon atoms which may have a monovalent substituent or a monovalent group in which —CH₂— constituting a monovalent aliphatic hydrocarbon group having 1 to 20 carbon atoms which may have a monovalent substituent is substituted with a divalent substituent,
na and nc each independently represent an integer of 0 to 3, where na+nc is 2 or greater,
where in a case where R^{a1} and R^{a2} represent the same group, —N(R^{b11})(R^{b12}) and —N(R^{b21})(R^{b22}) are groups different from each other, and in a case where R^{a1} and R^{a2} represent different groups, —N(R^{b11})(R^{b12}) and —N(R^{b21})(R^{b22}) may be groups that are the same as or different from each other.

2. The light absorption anisotropic film according to claim 1,
wherein the total content of the dichroic substance represented by Formula (C-1) and the dichroic substance represented by Formula (C-2) is 6.5% by mass or greater with respect to the total mass of the solid content of the liquid crystal composition.

3. The light absorption anisotropic film according to claim 1,
wherein a mass ratio of a content of the dichroic substance represented by Formula (C-1) to a content of the dichroic substance represented by Formula (C-2) in the liquid crystal composition is in a range of 0.100 to 10.0.

4. The light absorption anisotropic film according to claim 1,
wherein in Formula (C-1), a value of a Hansen solubility parameter of R^{b12} is greater than or equal to a value of a Hansen solubility parameter of R^{b11},
in Formula (C-2), a value of a Hansen solubility parameter of R^{b22} is greater than or equal to a value of a Hansen solubility parameter of R^{b21},
an absolute value of a difference in the Hansen solubility parameter between R^{b12} in Formula (C-1) and R^{b22} in Formula (C-2) is 3.0 or less.

5. The light absorption anisotropic film according to claim 4,
wherein the absolute value of the difference in the Hansen solubility parameter between R^{b12} in Formula (C-1) and R^{b22} in Formula (C-2) is 1.0 or less.

6. The light absorption anisotropic film according to claim 1,
wherein R^{b22} in Formula (C-2) represents a monovalent aliphatic hydrocarbon group having 1 to 20 carbon atoms which has a monovalent substituent or a monovalent group in which —CH₂— constituting a monovalent aliphatic hydrocarbon group having 1 to 20 carbon atoms which may have a monovalent substituent is substituted with a divalent substituent.

7. The light absorption anisotropic film according to claim 1,
wherein in R^{b12} in Formula (C-1),
the monovalent substituent is a hydroxyl group, a halogen atom, a cyano group, or a sulfonic acid group, and
the divalent substituent is —O—, —C(═O)—, —N(R^{c1})—, or a group obtained by combining two or more of these groups, where R^{c1} represents a hydrogen atom or an alkyl group.

8. The light absorption anisotropic film according to claim 1,
wherein the liquid crystal compound includes a polymer liquid crystal compound.

9. An optical film comprising:
a transparent film base material; and
the light absorption anisotropic film according to claim 1 which is disposed on the transparent film base material.

10. The optical film according to claim 9, further comprising:
an alignment film between the transparent film base material and the light absorption anisotropic film.

11. The optical film according to claim 9, further comprising:
a polarizer which has an absorption axis in a plane,
wherein the optical film is used to control a viewing angle.

12. A display device comprising:
the optical film according to claim 11; and
a display element.

13. The light absorption anisotropic film according to claim 2,
wherein a mass ratio of a content of the dichroic substance represented by Formula (C-1) to a content of the dichroic substance represented by Formula (C-2) in the liquid crystal composition is in a range of 0.100 to 10.0.

14. The light absorption anisotropic film according to claim 2,
wherein in Formula (C-1), a value of a Hansen solubility parameter of R^{b12} is greater than or equal to a value of a Hansen solubility parameter of R^{b11},
in Formula (C-2), a value of a Hansen solubility parameter of R^{b22} is greater than or equal to a value of a Hansen solubility parameter of R^{b21},
an absolute value of a difference in the Hansen solubility parameter between R^{b12} in Formula (C-1) and R^{b22} in Formula (C-2) is 3.0 or less.

15. The light absorption anisotropic film according to claim 14,
wherein the absolute value of the difference in the Hansen solubility parameter between R^{b12} in Formula (C-1) and R^{b22} in Formula (C-2) is 1.0 or less.

16. The light absorption anisotropic film according to claim 2,
wherein R^{b22} in Formula (C-2) represents a monovalent aliphatic hydrocarbon group having 1 to 20 carbon atoms which has a monovalent substituent or a monovalent group in which —CH₂— constituting a monovalent aliphatic hydrocarbon group having 1 to 20 carbon atoms which may have a monovalent substituent is substituted with a divalent substituent.

17. The light absorption anisotropic film according to claim 2,
wherein in R^{b12} in Formula (C-1),
the monovalent substituent is a hydroxyl group, a halogen atom, a cyano group, or a sulfonic acid group, and
the divalent substituent is —O—, —C(═O)—, —N(R^{c1})—, or a group obtained by combining two or more of these groups, where R^{c1} represents a hydrogen atom or an alkyl group.

18. The light absorption anisotropic film according to claim 2,
wherein the liquid crystal compound includes a polymer liquid crystal compound.

19. An optical film comprising:
a transparent film base material; and
the light absorption anisotropic film according to claim 2 which is disposed on the transparent film base material.

20. The optical film according to claim 19, further comprising:
an alignment film between the transparent film base material and the light absorption anisotropic film.
